(19) United States
(12) Patent Application Publication
(10) Pub. No.: US 2024/0215288 A1
(43) Pub. Date: Jun. 27, 2024

(54) ORGANIC LIGHT EMITTING DIODE AND ORGANIC LIGHT EMITTING DEVICE

(71) Applicant: LG Display Co., Ltd., Seoul (KR)

(72) Inventors: Sung-Min JO, Paju-si (KR); Hong-Seok CHOI, Paju-si (KR); Sun-Hee LEE, Paju-si (KR)

(73) Assignee: LG Display Co., Ltd., Seoul (KR)

(21) Appl. No.: 18/229,358

(22) Filed: Aug. 2, 2023

(30) Foreign Application Priority Data
Dec. 9, 2022 (KR) 10-2022-0171069

(51) Int. Cl. H10K 50/125; H10K 50/814; H10K 50/82; H10K 77/10; H10K 85/60

(52) U.S. Cl. CPC H10K 50/125; H10K 50/814; H10K 50/82; H10K 77/10; H10K 85/622; H10K 85/653; H10K 2102/101

(57) ABSTRACT

An organic light emitting diode (OLED) is described, where a red emitting material layer, a first blue emitting material layer and a second blue emitting material layer are disposed sequentially between two electrodes. A first blue host in the first blue emitting material layer has a hole mobility faster than a hole mobility of a second blue host in the second blue emitting material layer. Holes and electrons are injected into an emitting material layer in balance so that an exciton recombination zone is formed within the emitting material layer. Red and blue emission efficiencies are controlled in balance so that an OLED with beneficial blue emission efficiency and high red emission lifetime can be realized. An organic light emitting device includes the organic light emitting diode, and can be a display device or a lighting device.

### CROSS-REFERENCE TO RELATED APPLICATIONS

This application claims priority, under 35 U.S.C. § 119(a), to Korean Patent Application No. 10-2022-0171069, filed in the Republic of Korea on Dec. 9, 2022, the entire contents of which are hereby expressly incorporated in their entirely into the present application.

### BACKGROUND

### Technical Field

The present disclosure relates to an organic light emitting diode (OLED), and more particularly, to an organic light emitting diode that has improved luminous efficiency and luminous lifespan, and an organic light emitting device including thereof.

### Description of the Related Art

Flat display devices including an organic light emitting diode (OLED) are increasingly being used in various applications, and have advantages over a liquid crystal display device (LCD). For instance, the OLED can implement unidirectional or bidirectional images by electrode configurations. Also, the OLED can be formed even on a flexible transparent substrate, e.g., such as a plastic substrate, so that a flexible or a foldable display device can easily be provided using the OLED. In addition, the OLED can be driven at a lower voltage and the OLED has advantageous high color purity compared to an LCD.

However, there remains a need to develop OLEDs and devices thereof that have improved luminous efficiency and luminous lifespan. Since fluorescent materials use only singlet excitons in the luminous process, there is an issue with low luminous efficiency. Meanwhile, phosphorescent materials can show high luminous efficiency since they use triplet exciton as well as singlet excitons in the luminous process. But, examples of such phosphorescent material include metal complexes, which can have a luminous lifespan that is too short for commercial use. As such, there remains a need to develop an OLED with sufficient luminous properties and luminous lifetime.

### SUMMARY OF THE DISCLOSURE

Embodiments of the present disclosure are directed to an organic light emitting diode and an organic light emitting device that substantially obviate one or more of the problems due to the limitations and disadvantages of the related art.

An organic light-emitting diode according to aspects of the invention can operate at a low voltage, consume less power, render excellent colors, and/or can be used in a variety of applications. In an aspect, the OLED can also be formed on a flexible substrate, to provide a flexible or a foldable device. Further, the size of the OLED can be easily adjustable.

An aspect of the present disclosure is to provide an organic light emitting diode that has improved luminous efficiency and an organic light emitting device including the organic light emitting diode.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other advantages and in accordance with objects of the disclosure, as embodied and broadly described herein, in one aspect, the present disclosure provides an organic light emitting diode that includes a first electrode; a second electrode facing the first electrode; and an emissive layer disposed between the first electrode and the second electrode, and including at least one emitting material layer, wherein the at least one emitting material layer includes: a red emitting material layer; a first blue emitting material layer disposed between the red emitting material layer and the second electrode and including a first blue host; and a second blue emitting material layer disposed between the first blue emitting material layer and the second electrode and including a second blue host, and wherein the first blue host has a hole mobility faster than a hole mobility of the second blue host. In one example embodiment, the hole mobility of the first blue host can be about 1.5 to about 50000 times, e.g., about 5, 10, 50, 100, 200, 500, 1000, 1500, 2000, 2200, 2500, 2550, 2700, 3000, 5000, 10000, 20000, 25000, 30000, or about 40000 times that of the second blue host.

The first blue host can have electron mobility slower than an electron mobility of the second blue host. In one example embodiment, the electron mobility of the second blue host can be about 1.1 to about 5000 times, e.g., about 1.5, 5, 10, 15, 18, 20, 22, 25, 30, 50, 100, 200, 500, 1000, 2000, 3000, or about 4000 times that of the first blue host.

The second blue host can have a highest occupied molecular orbital (HOMO) energy level lower than a HOMO energy level of the first blue host. In one example embodiment, the difference between the HOMO energy level of the first blue host and that of the second blue host can be about 0.1 eV to about 1.0 eV, e.g., about 0.1 eV to 0.5 eV.

The first blue host can include an organic compound having the following structure of Chemical Formula 1:

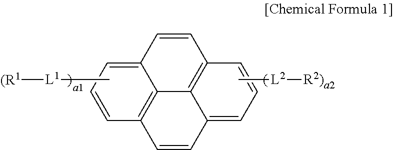

wherein, in Chemical Formula 1,
each of R¹ and R² is independently an unsubstituted or substituted C₆-C₃₀ aryl group or an unsubstituted or substituted C₃-C₃₀ hetero aryl group;
each of L¹ and L² is independently a single bond, an unsubstituted or substituted C₆-C₃₀ arylene group or an unsubstituted or substituted C₃-C₃₀ hetero arylene group; and
each of a1 and a2 is independently 1, 2 or 3, where each R¹-L¹- is identical to or different from each other when a1 is 2 or 3 and each R²-L²- is identical to or different from each other when a2 is 2 or 3.

The second blue host can include an organic compound having the following structure of Chemical Formula 3:

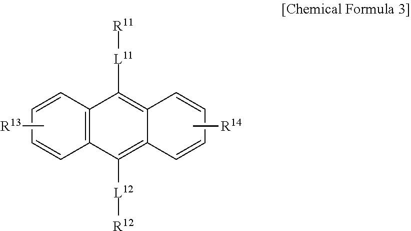

wherein, in Chemical Formula 3,
each of R¹¹ and R¹² is independently an unsubstituted or substituted C₆-C₃₀ aryl group or an unsubstituted or substituted C₃-C₃₀ hetero aryl group;
each of R¹³ and R¹⁴ is independently hydrogen, an unsubstituted or substituted C₁-C₂₀ alkyl group, an unsubstituted or substituted C₆-C₃₀ aryl group or an unsubstituted or substituted C₃-C₃₀ hetero aryl group; and
L¹¹ and L¹² is independently a single bond, an unsubstituted or substituted C₆-C₃₀ arylene group or an unsubstituted or substituted C₃-C₃₀ hetero arylene group.

In certain embodiments, in Chemical Formula 1, each R¹ is independently selected from substituted or unsubstituted dibenzothiophenyl, substituted or unsubstituted benzofuran; each L¹ is independently selected from direct bond, phenyl, naphthyl or anthracenyl; each R² is independently selected from substituted or unsubstituted dibenzothiophenyl, substituted or unsubstituted benzofuran; and each L² is independently selected from direct bond, phenyl, naphthyl or anthracenyl.

In certain embodiments, in Chemical Formula 1, each L¹ is independently selected from substituted or unsubstituted dibenzothiophenyl, substituted or unsubstituted benzofuran; each R¹ is independently selected from phenyl, naphthyl or anthracenyl; each L² is independently selected from substituted or unsubstituted dibenzothiophenyl, substituted or unsubstituted benzofuran; and each R² is independently selected from phenyl, naphthyl or anthracenyl.

In another aspect, each (R¹)ₐ₁-L¹- moiety is independently selected from the group consisting of:

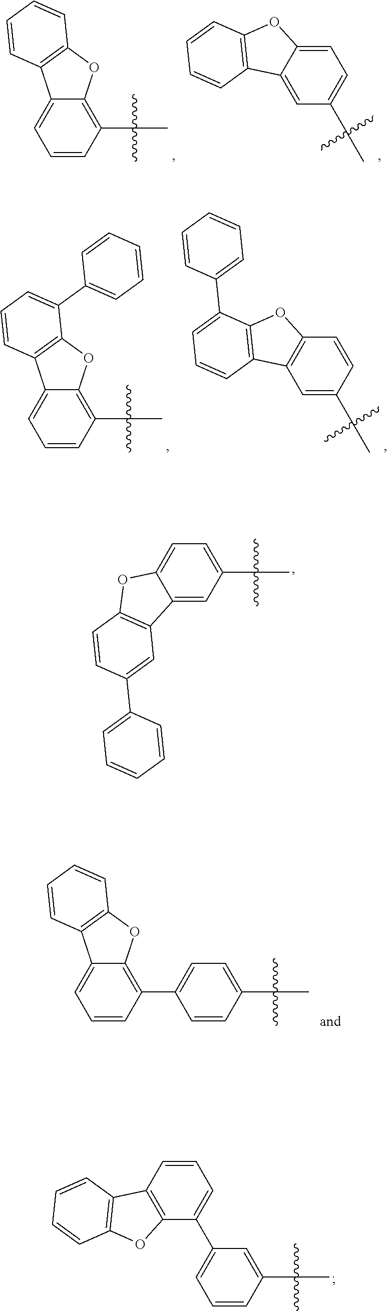

each (R²)ₐ₂-L²- is independently selected from the group consisting of: phenyl,

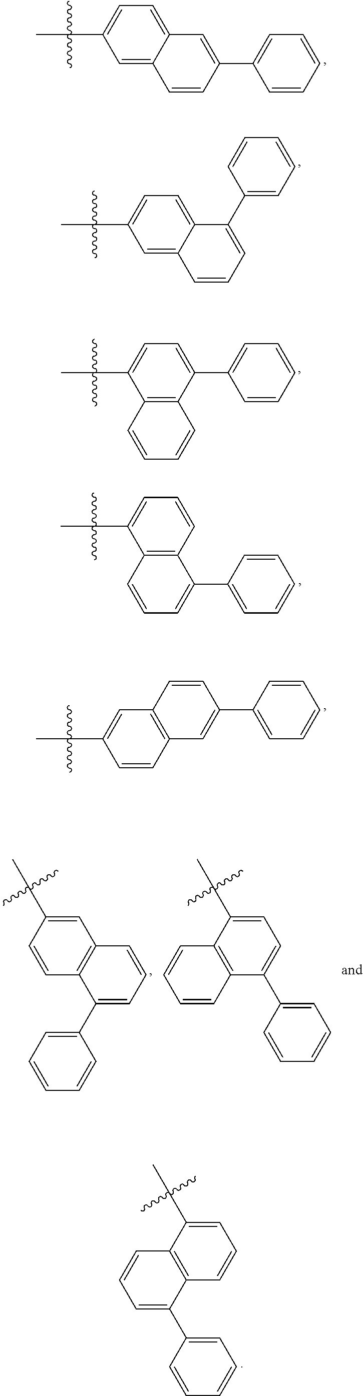

The red emitting material layer can include a red host and a red emitter, and wherein the red host can have hole mobility faster than the hole mobility of the second blue host.

In one embodiment, the emissive layer can have a single emitting unit. In one example embodiment, the hole mobility of the red host can be about 1.5 to about 50000 times, e.g., about 5, 10, 50, 100, 200, 500, 1000, 1500, 2000, 2200, 2500, 2550, 2700, 3000, 5000, 10000, 20000, 25000, 30000, or about 40000 times that of the second blue host.

In another embodiment, the emissive layer can include: a first emitting part disposed between the first electrode and the second electrode; a second emitting part disposed between the first emitting part and the second electrode; a third emitting part disposed between the second emitting part and the second electrode; a fourth emitting part disposed between the third emitting part and the second electrode; a first charge generation layer disposed between the first emitting part and the second emitting part; a second charge generation layer disposed between the second emitting part and the third emitting part; and a third charge generation layer disposed between the third emitting part and the fourth emitting part, and wherein one of the first to fourth emitting parts can include the at least one emitting material layer.

As an example, the first emitting part can include the at least one emitting material layer.

In another aspect, the present disclosure provides an organic light emitting diode including: a first electrode; a second electrode facing the first electrode; and an emissive layer disposed between the first electrode and the second electrode, wherein the emissive layer includes: a first emitting part disposed between the first electrode and the second electrode; a second emitting part disposed between the first emitting part and the second electrode; a third emitting part disposed between the second emitting part and the second electrode; a fourth emitting part disposed between the third emitting part and the second electrode; a first charge generation layer disposed between the first emitting part and the second emitting part; a second charge generation layer disposed between the second emitting part and the third emitting part; and a third charge generation layer disposed between the third emitting part and the fourth emitting part, wherein the first emitting part includes: a red emitting material layer disposed between the first electrode and the first charge generation layer; a first blue emitting material layer disposed between the red emitting material layer and the first charge generation layer and including a first blue host; and a second blue emitting material layer disposed between the first blue emitting material layer and the first charge generation layer, wherein the second emitting part includes the third blue emitting material layer, the fourth emitting part includes the fourth blue emitting material layer and the third emitting part includes a green emitting material layer, and wherein the first blue host has hole mobility faster than hole mobility of the second blue host.

In another aspect, the present disclosure provides an organic light emitting device, for example, an organic light illumination device or an organic light emitting diode display device that includes the organic light emitting diode disposed over a substrate.

The organic light emitting diode includes two blue emitting material layers disposed adjacently to the red emitting material layer. The first blue host in the first blue emitting material layer can have a LUMO (lowest occupied molecular orbital) energy level and/or a HOMO (highest occupied molecular orbital) energy level different from a LUMO energy level and/or HOMO energy level of the second blue host in the second blue emitting material layer.

In one or more embodiment, the first blue emitting material layer disposed adjacently to a hole transport layer includes the first blue host with relatively beneficial hole mobility and the second blue emitting material layer disposed adjacently to an electron transport layer includes the second blue host with a relatively low HOMO energy level and/or LUMO energy level.

The first blue host has beneficial hole mobility and the second blue host has beneficial electron mobility. Holes injected from the hole transport layer and the electrons injected from the electron transport layer can be recombined to form excitons at an interface between the first blue emitting material layer and the second blue emitting material layer. Stable blue luminous efficiency can be maintained as the exciton recombination zone is formed within the emitting material layer in the embodiments of the present disclosure.

It is possible to minimize amounts of non-emissive excitons as the excitons are not lost outside of the emitting material layer. Excitons are not quenched by triplet-triplet annihilation (TTA) and/or triplet-polaron annihilation (TPA). It is possible to minimize the degradation of the luminous materials in the red emitting material layer, which is disposed distantly from the interface between two blue emitting material layers, by non-emissive excitons because the exciton recombination zone is formed at the interface between the first and second blue emitting material layers in the embodiments of the present disclosure.

In one or more embodiments, the second blue emitting material layer including the second blue host with a relatively low HOMO energy level prevents holes from leaking to the electron transport layer. Exciton quenching at an interface between the emitting material layer and the electron transport layer is minimized so that the driving voltage of the organic light emitting diode can be lowered in the embodiments of the present disclosure.

The organic light emitting diode can maintain blue luminous efficiency stably with securing red luminous lifetime stably. The blue and red luminous efficiency can be maintained stably and stable red luminous lifetime can be secured in the embodiments of the present disclosure.

It is to be understood that both the foregoing general description and the following detailed description are merely by way of example and are intended to provide further explanation of the inventive concepts as claimed.

### BRIEF DESCRIPTION OF THE DRAWINGS

The accompanying drawings, which are included to provide a further understanding of the disclosure, are incorporated in and constitute a part of this application, illustrate embodiments of the disclosure and together with the description serve to explain principles of the disclosure.

FIG. 1 illustrates a schematic circuit diagram of an organic light emitting display device in accordance with one or more embodiments of the present disclosure.

FIG. 2 illustrates a cross-sectional view of an organic light emitting display device as an example of an organic light emitting device in accordance with an example embodiment of the present disclosure.

FIG. 3 illustrates a cross-sectional view of an organic light emitting diode having a single emitting part in accordance with an example embodiment of the present disclosure.

FIG. 4 illustrates a schematic diagram showing energy levels of host and charge transporting materials in one comparative organic light emitting diode where a single blue emitting material layer including a blue host with relatively slow hole mobility and a red emitting material layers are disposed adjacently.

FIG. 5 illustrates a schematic diagram showing energy levels of host and charge transporting materials in another comparative organic light emitting diode where a single blue emitting material layer including a blue host with relatively fast hole mobility and a red emitting material layers are disposed adjacently.

FIG. 6 illustrates a schematic diagram showing energy levels of host and charge transporting materials in an embodiment of an organic light emitting diode where two blue emitting material layers each of which includes a blue host with controlled charge mobility and a red emitting material layers are disposed adjacently.

FIG. 7 illustrates a cross-sectional view of an organic light emitting display device in accordance with another example embodiment of the present disclosure.

FIG. 8 illustrates a cross-sectional view of an organic light emitting diode having a tandem structure of two emitting parts in accordance with another example embodiment of the present disclosure.

FIG. 9 illustrates an example of electroluminescence (EL) spectra of organic light emitting diodes fabricated as described in the following Examples of the present disclosure and Comparative Examples.

FIG. 10 illustrates an example of red luminous lifetime of organic light emitting diodes fabricated as described in the following Examples of the present disclosure and Comparative Examples.

### DETAILED DESCRIPTION OF THE EMBODIMENTS

Reference will now be made in detail to aspects of the disclosure, examples of which are illustrated in the accompanying drawings. Wherever possible, the same reference numbers will be used throughout the drawings to refer to the same or like parts. All the components of each OLED and each organic light emitting display device according to all embodiments of the present disclosure are operatively coupled and configured.

The present disclosure relates to an organic emitting diode and/or an organic light emitting device where plural blue emitting material layers each of which includes luminous material with controlled energy level and/or charge mobility are disposed adjacently to a red emitting material layer, e.g., to maintain the blue and red luminous efficiency stably and to maximize luminous lifetime thereof.

As an example, in one or more embodiments of the present disclosure, the emissive layer in the organic light emitting diode can be applied to an organic light emitting diode with a single emitting unit in a red and/or blue pixel region. Alternatively, the emissive layer can be applied to an organic light emitting diode having a tandem structure where two or more emitting parts are stacked. The organic light emitting diode can be applied to an organic light emitting device such as an organic light emitting display device or an organic light emitting illumination device.

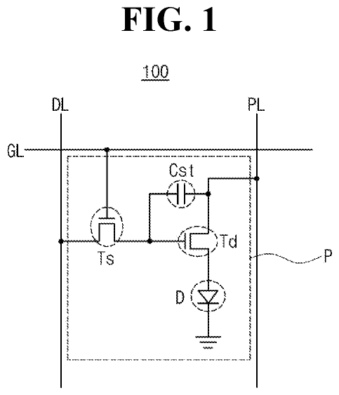

FIG. 1 illustrates a schematic circuit diagram of an organic light emitting display device in accordance with one or more embodiments of the present disclosure.

As illustrated in FIG. 1, a gate line GL, a data line DL and power line PL, each of which crosses each other to define a pixel region P, in an organic light emitting display device 100. A switching thin film transistor Ts, a driving thin film transistor Td, a storage capacitor Cst and an organic light emitting diode D are disposed within the pixel region P. The pixel region P can include a red (R) pixel region, a green (G) pixel region and a blue (B) pixel region. However, embodiments of the present disclosure are not limited to such examples. The organic light emitting display device 100 includes a plurality of such pixel regions P which can be arranged in a matrix configuration or other configurations. Further, each pixel region P can include one or more subpixels.

The switching thin film transistor Ts is connected to the gate line GL and the data line DL. The driving thin film transistor Td and the storage capacitor Cst are connected between the switching thin film transistor Ts and the power line PL. The organic light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

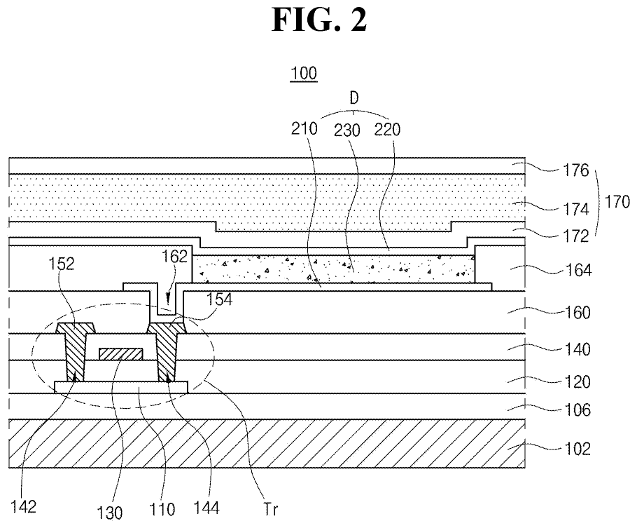

The driving thin film transistor Td is turned on by the data signal applied to the gate electrode 130 (FIG. 2) so that a current proportional to the data signal is supplied from the power line PL to the organic light emitting diode D through the driving thin film transistor Td. Then, the organic light emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the organic light emitting display device can display a desired image.

FIG. 2 illustrates a schematic cross-sectional view of an organic light emitting display device in accordance with an example embodiment of the present disclosure. The pixel circuit configuration of FIG. 1 can be used in the display device of FIG. 2 or other figures of the present application.

As illustrated in FIG. 2, the organic light emitting display device 100 includes a substrate 102, a thin-film transistor Tr on the substrate 102, and an organic light emitting diode (OLED) D connected to the thin film transistor Tr. As an example, the substrate 102 can include a red pixel region, a green pixel region and a blue pixel region and an OLED D can be located in each pixel region. Each of the OLED D emitting red, green and blue light, respectively, is located correspondingly in the red pixel region, the green pixel region and the blue pixel region. As an example, the organic light emitting diode D can be located in the red pixel region and/or the blue pixel region.

The substrate 102 can include, but is not limited to, glass, thin flexible material and/or polymer plastics. For example, the flexible material can be selected from the group, but is not limited to, polyimide (PI), polyethersulfone (PES), polyethylenenaphthalate (PEN), polyethylene terephthalate (PET), polycarbonate (PC) and/or combinations thereof. The substrate 102, on which the thin film transistor Tr and the organic light emitting diode D are arranged, forms an array substrate.

A buffer layer 106 can be disposed on the substrate 102. The thin film transistor Tr can be disposed on the buffer layer 106. In certain embodiments, the buffer layer 106 can be omitted.

A semiconductor layer 110 is disposed on the buffer layer 106. In one example embodiment, the semiconductor layer 110 can include, but is not limited to, oxide semiconductor materials. In this case, a light-shield pattern can be disposed under the semiconductor layer 110, and the light-shield pattern can prevent light from being incident toward the semiconductor layer 110, and thereby, preventing or reducing the semiconductor layer 110 from being degraded by the light. Alternatively, the semiconductor layer 110 can include polycrystalline silicon. In this case, opposite edges of the semiconductor layer 110 can be doped with impurities.

A gate insulating layer 120 including an insulating material is disposed on the semiconductor layer 110. The gate insulating layer 120 can include, but is not limited to, an inorganic insulating material such as silicon oxide (SiOₓ, wherein 0<x≤2) or silicon nitride (SiNₓ, wherein 0<x≤2).

A gate electrode 130 made of a conductive material such as a metal is disposed on the gate insulating layer 120 so as to correspond to a center of the semiconductor layer 110. While the gate insulating layer 120 is disposed on the entire area of the substrate 102 as shown in FIG. 2, the gate insulating layer 120 can be patterned identically as the gate electrode 130.

An interlayer insulating layer 140 including an insulating material is disposed on the gate electrode 130 and covers an entire surface of the substrate 102. The interlayer insulating layer 140 can include, but is not limited to, an inorganic insulating material such as silicon oxide (SiOₓ, wherein 0<x≤2) or silicon nitride (SiNₓ, wherein 0<x≤2), or an organic insulating material such as benzocyclobutene or photo-acryl.

The interlayer insulating layer 140 has a first semiconductor layer contact hole 142 and a second semiconductor layer contact hole 144 that can expose or do not cover a portion of the surface nearer to the opposing ends than to a center of the semiconductor layer 110. The first and second semiconductor layer contact holes 142 and 144 are disposed on opposite sides of the gate electrode 130 and spaced apart from the gate electrode 130. The first and second semiconductor layer contact holes 142 and 144 are formed within the gate insulating layer 120 in FIG. 2. Alternatively, in certain embodiments, the first and second semiconductor layer contact holes 142 and 144 can be formed only within the interlayer insulating layer 140 when the gate insulating layer 120 is patterned identically as the gate electrode 130.

A source electrode 152 and a drain electrode 154, which are made of conductive material such as a metal, are disposed on the interlayer insulating layer 140. The source electrode 152 and the drain electrode 154 are spaced apart from each other on opposing sides of the gate electrode 130, and contact both sides of the semiconductor layer 110 through the first and second semiconductor layer contact holes 142 and 144, respectively. Here, the designation of the source and drain electrodes 152 and 154 can be switched with each other depending on the type and configuration of a transistor.

The semiconductor layer 110, the gate electrode 130, the source electrode 152 and the drain electrode 154 constitute the thin film transistor Tr, which acts as a driving element. The thin film transistor Tr in FIG. 2 has a coplanar structure in which the gate electrode 130, the source electrode 152 and the drain electrode 154 are disposed on the semiconductor layer 110. Alternatively, the thin film transistor Tr can have an inverted staggered structure in which a gate electrode is disposed under a semiconductor layer and a source and drain electrodes are disposed on the semiconductor layer. In this case, the semiconductor layer can include amorphous silicon.

The gate line GL and the data line DL, which cross each other to define a pixel region P, and a switching element Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL. The thin film transistor Tr can further include a storage capacitor Cst configured to constantly keep a voltage of the gate electrode 130 for one frame.

A passivation layer 160 is disposed on the source and drain electrodes 152 and 154. The passivation layer 160 covers the thin film transistor Tr on the entire substrate 102. The passivation layer 160 has a flat top surface and a drain contact hole 162 that exposes or does not cover the drain electrode 154 of the thin film transistor Tr. While the drain contact hole 162 is disposed on the second semiconductor layer contact hole 144, it can be spaced apart from the second semiconductor layer contact hole 144.

The organic light emitting diode (OLED) D includes a first electrode 210 that is disposed on the passivation layer 160 and connected to the drain electrode 154 of the thin film transistor Tr. The OLED D further includes an emissive layer 230 and a second electrode 220 each of which is disposed sequentially on the first electrode 210.

The first electrode 210 is disposed separately in each pixel region. The first electrode 210 can be an anode and include conductive material having relatively high work function value. For example, the first electrode 210 can include a transparent conductive oxide (TCO). More particularly, the first electrode 210 can include, but is not limited to, indium tin oxide (ITO), indium zinc oxide (IZO), indium tin zinc oxide (ITZO), tin oxide (SnO), zinc oxide (ZnO), indium cerium oxide (ICO), aluminum doped zinc oxide (AZO), and/or combinations thereof.

In one example embodiment, when the organic light emitting display device 100 is a bottom-emission type, the first electrode 210 can have a single-layered structure of the TCO. Alternatively, when the organic light emitting display device 100 is a top-emission type, a reflective electrode or a reflective layer can be disposed under the first electrode 210. For example, the reflective electrode or the reflective layer can include, but is not limited to, silver (Ag) or aluminum-palladium-copper (APC) alloy. In the OLED D of the top-emission type, the first electrode 210 can have a triple-layered structure of ITO/Ag/ITO or ITO/APC/ITO.

In addition, a bank layer 164 is disposed on the passivation layer 160 in order to cover edges of the first electrode 210. The bank layer 164 exposes or does not cover a center of the first electrode 210 corresponding to each pixel region. In certain embodiments, the bank layer 164 can be omitted.

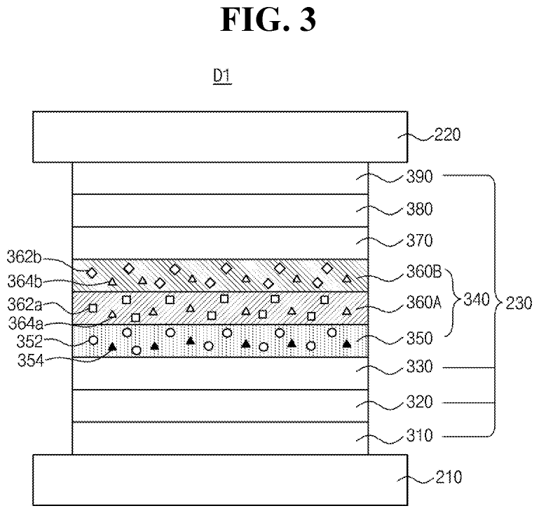

An emissive layer 230 is disposed on the first electrode 210. In one example embodiment, the emissive layer 230 can have a single-layered structure of an emitting material layer (EML). Alternatively, the emissive layer 230 can have a multiple-layered structure of a hole injection layer (HIL), a hole transport layer (HTL), an electron blocking layer (EBL), an EML, a hole blocking layer (HBL), an electron transport layer (ETL), an electron injection layer (EIL) and/or a charge generation layer (CGL) (FIG. 3). In one example embodiment, the emissive layer 230 can have a single emitting part. Alternatively, the emissive layer 230 can have multiple emitting parts to form a tandem structure.

The emissive layer 230 can include plural blue emitting material layers each of which includes a different host with controlled energy level and/or charge mobility.

The second electrode 220 is disposed on the substrate 102 above which the emissive layer 230 is disposed. The second electrode 220 can be disposed on the entire display area. The second electrode 220 can include a conductive material with a relatively low work function value compared to the first electrode 210. The second electrode 220 can be a cathode providing electrons. For example, the second electrode 220 can include at least one of, but is not limited to, aluminum (Al), magnesium (Mg), calcium (Ca), silver (Ag), alloy thereof and/or combinations thereof such as aluminum-magnesium alloy (Al—Mg). When the organic light emitting display device 100 is a top-emission type, the second electrode 220 is thin so as to have light-transmissive (semi-transmissive) property.

In addition, an encapsulation film 170 can be disposed on the second electrode 220 in order to prevent or reduce outer moisture from penetrating into the OLED D. The encapsulation film 170 can have, but is not limited to, a laminated structure of a first inorganic insulating film 172, an organic insulating film 174 and a second inorganic insulating film 176. In certain embodiments, the encapsulation film 170 can be omitted.

The organic light emitting display device 100 can include a polarizing plate to reduce reflection of external light. For example, the polarizing plate can be a circular polarizing plate. When the organic light emitting display device 100 is a bottom-emission type, the polarizing plate can be disposed under the substrate 102. Alternatively, when the organic light emitting display device 100 is a top-emission type, the polarizing plate can be disposed on the encapsulation film 170. In addition, a cover window can be attached to the encapsulation film 170 or the polarizing plate. In this case, the substrate 102 and the cover window can have a flexible property, thus the organic light emitting display device 100 can be a flexible display device.

In addition, a color filter layer can be disposed between the substrate 102 and the OLED D, or on the OLED D. The color filter layer can include a red color filter layer and/or a blue color filter layer, and the organic light emitting display device 100 can be located in the red pixel region and/or the blue pixel region. However, different combinations of color filter layers can be provided, e.g., a red color filter layer, a blue color filter layer and a green color filter layer.

The OLED D is described in more detail. FIG. 3 illustrates a schematic cross-sectional view of an organic light emitting diode having a single emitting part in accordance with an example embodiment of the present disclosure.

As illustrated in FIG. 3, the organic light emitting diode (OLED) D1 in accordance with the present disclosure includes first and second electrodes 210 and 220 facing each other and an emissive layer 230 disposed between the first and second electrodes 210 and 220. The organic light emitting display device 100 includes a red pixel region, a green pixel region and a blue pixel region, and the OLED D1 can be disposed in the red pixel region and/or the blue pixel region.

In an example embodiment, the emissive layer 230 includes an emitting material layer (EML) 340 disposed between the first and second electrodes 210 and 220. Also, the emissive layer 230 can include at least one of a hole transport layer (HTL) 320 disposed between the first electrode 210 and the EML 340 and an electron transport layer (ETL) 380 disposed between the second electrode 220 and the EML 340. In addition, the emissive layer 230 can further include at least one of a hole injection layer (HIL) 310 disposed between the first electrode 210 and the HTL 320 and an electron injection layer (EIL) 390 disposed between the second electrode 220 and the ETL 380. Alternatively, the emissive layer 230 can further comprise a first exciton blocking layer, i.e., an electron blocking layer (EBL) 330 disposed between the HTL 320 and the EML 340 and/or a second exciton blocking layer, i.e., a hole blocking layer (HBL) 370 disposed between the EML 340 and the ETL 380.

The first electrode 210 can be an anode that provides a hole into the EML 340. The first electrode 210 can include a conductive material having a relatively high work function value, for example, a transparent conductive oxide (TCO). In an example embodiment, the first electrode 210 can include, but is not limited to, ITO, IZO, ITZO, SnO, ZnO, ICO, AZO, and/or combinations thereof.

The second electrode 220 can be a cathode that provides an electron into the EML 340. The second electrode 220 can include a conductive material having a relatively low work function values, i.e., a highly reflective material such as Al, Mg, Ca, Ag, and/or alloy thereof and/or combinations thereof such as Al—Mg. For example, each of the first electrode 210 and the second electrode 220 can have, but is not limited to, a thickness of about 10 nm to about 300 nm.

The EML 340 includes a red emitting material layer (R-EML) 350, a first blue emitting material layer (B-EML1) 360A disposed between the R-EML 350 and the HBL 370, and a second blue emitting material layer (B-EML2) 360B disposed between the B-EML1 360A and the HBL 370.

The R-EML 350 includes a red host 352 and a red emitter (red dopant) 354. The B-EML 1 360A includes a first blue host 362a and a first blue emitter (first blue dopant) 364a and the B-EML2 360B includes a second blue host 362b, and optionally, a second blue emitter (second blue dopant) 364b. Substantial or ultimate emission is occurred at the red emitter 354, the first blue emitter 364a and the second blue emitter 364b in the R-EML 350, the B-EML1 360A and the B-EML2 360B, respectively.

The red host 352 can be at least one of a P-type red host and an N-type red host. As an example, the red host 352 can be the P-type red host, and in this case, the R-EML 350 can further include the N-type red host. The red host 352 can include, but is not limited to, an organic compound with hole mobility higher than electron mobility such as a carbazole-based organic compound, an amine-based organic compound substituted with at least one of aryl and/or hetero aryl and/or a spirofluorene-based organic compound.

More particularly, the red host 352 can include, but is not limited to, 4,4′-bis(N-carbazolyl)-1,1′-biphenyl (CBP), 3,3′-Di(9H-carbazol-9-yl)-1,1′-biphenyl (mCBP), 2,2′-Di(9H-carbazol-9yl)-1,1′-biphenyl (oCBP), 1,3-Di(9H-carbazol-9-yl)benzene (mCP), 9-(3-(9H-Carbazol-9-yl)phenyl)-9H-carbazole-3-carbonitrile (mCP-CN), Bis[2-(diphenylphosphino)phenyl]ether oxide (DPEPO), 2,8-bis(diphenylphosphoryl)dibenzothiophene (PPT), 1,3,5-Tri[(3-pyridyl)-phen-3-yl]benzene (TmPyPB), 2,6-Di(9H-carbazol-9-yl)pyridine (PYD-2Cz), 2,8-di(9H-carbazol-9-yl)dibenzothiophene (DCzDBT), 3′,5′-Di(carbazol-9-yl)-[1,1′-bipheyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), Diphenyl-4-triphenylsilyl-phenylphosphine oxide (TSPO1), 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicarbazole, 9,9′-Diphenyl-9H,9′H-3,3′-bicarbazole (BCzPh), 1,3,5-Tris(carbazol-9-yl)benzene (TCP), 4,4′-Bis(carbazole-9-yl)-2,2′-dimethylbipheyl (CDBP), 2,7-Bis(carbazole-9-yl)-9,9-dimethylfluorene (DMFL-CBP), 2,2′,7,7′-Tetrakis(carbazol-9-yl)-9,9-spirofluorene (Spiro-CBP), 3,6-Bis(carbazole-9-yl)-9-(2-ethyl-hexyl)-9H-carbazole (TCz1), N4,N4,N4′,N4′-Tetra[(1,1′-biphenyl)-4-yl]-(1,1′-biphenyl)-4,4′-diamine (BPBPA), 1,3,5-Tris(N-phenylbenzimidazol-2-yl)benzene (TBPi), Tris(4-carbazoyl-9-yl-phenyl)amine (TCTA) and/or combinations thereof.

For example, the red host 352 can include an organic compound with hole mobility relatively higher than electron mobility. In one example embodiment, the red host can include a hole injecting material and/or hole transporting material as described below. In another example embodiment, the red host 352 can have a hole mobility larger than the hole mobility of the second blue host 362b so that holes and electrons can be recombined to form excitons at an interface between the B-EML1 360A and the B-EML2 360B.

The red dopant 354 can include at least one of a red phosphorescent material, a red fluorescent material and a red delayed fluorescent material. As an example, the red emitter 354 can include, but is not limited to, Bis[2-(4,6-dimethyl)phenylquinoline)](2,2,6,6-tetramethylheptane-3,5-dionate)iridium(III), Bis[2-(4-n-hexylphenyl)quinoline](acetylacetonate)iridium(III) Tris [2-(4-n-(Hex-Ir(phq)₂(acac)), hexylphenyl)quinoline]iridium(III) (Hex-Ir(phq)₃), Tris[2-phenyl-4-methylquinoline]iridium(III) Bis(2-phenylquinoline)(2,2,6,6-tetramethylheptene-3,5-dionate)iridium(III) (Ir(Mphq)₃), (Ir(dpm)PQ₂), Tris(1-phenylisoquinoline)iridium(III) (Ir(piq)₃), Bis(phenylisoquinoline)(2,2,6,6-tetramethylheptene-3,5-dionate)iridium(III) (Ir(dpm)(piq)₂), Bis(1-phenylisoquinoline)(acetylacetonate)iridium(III) (Ir(piq)₂(acac)), Bis[(4-n-hexylphenyl)isoquinoline](acetylacetonate)iridium(III) Tris[2-(4-n-(Hex-Ir(piq)₂(acac)), hexylphenyl)quinoline]iridium(III) (Hex-Ir(piq)₃), Tris(2-(3-methylphenyl)-7-methyl-(Ir(dmpq)₃), Bis[2-(2-methylphenyl)-7-methyl-quinoline](acetylacetonate) quinolato)iridium iridium(III) (Ir(dmpq)₂(acac)), Bis[2-(3,5-dimethylphenyl)-4-methyl-quinoline](acetylacetonate)iridium(III) (Ir(mphmq)₂(acac)), Tris(dibenzoylmethane)mono(1,10-phenanthroline)europium(III) (Eu(dbm)₃(phen) and/or combinations thereof.

In one example embodiment, the contents of the red host 352 in the R-EML 350 can be about 50 wt % to about 99 wt %, for example, about 80 wt % to about 95 wt %, and the contents of the red emitter 354 in the R-EML 350 can be about 1 wt % to about 50 wt %, for example, about 5 wt % to about 20 wt %, but is not limited thereto. When the R-EML 350 includes the P-type red host and the N-type red host, the P-type red host and the N-type red host in the R-EML 350 can be admixed, but is not limited to, with a weight ratio of about 4:1 to about 1:4, for example about 3:1 to about 1:3.

The first blue host 362a has relatively high hole affinity and the second blue host 362b has relatively high electron affinity. In other words, the first blue host 362a has hole mobility faster than hole mobility of the second blue host 362b and the second blue host 362b has electron mobility faster than electron mobility of the first blue host 362a. Alternatively, each of the first blue host 362a and the second blue host 362b can have the hole mobility slower than the electron mobility thereof.

In another example embodiment, the second blue host 362b can have a highest occupied molecular orbital (HOMO) energy level lower than the HOMO energy level of the first blue host 362a and/or a lowest unoccupied molecular orbital (LUMO) energy level lower than the LUMO energy level of the first blue host 362a. The first blue host 362a and the second blue host 362b with controlled charge mobility and energy levels can cause the OLED D1 to exhibit beneficial luminous properties.

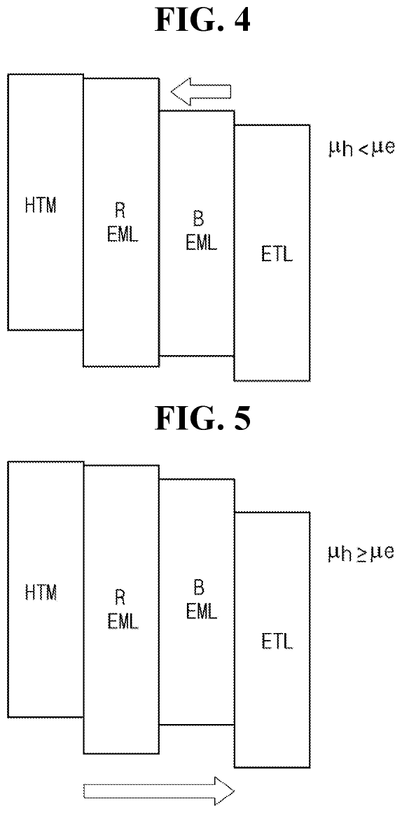

FIG. 4 illustrates a schematic diagram showing energy levels of host and charge transporting materials in one comparative organic light emitting diode where a single blue emitting material layer including a blue host with a relatively slow hole mobility and a red emitting material layers are disposed adjacently.

Referring to FIG. 4, in a red-blue junction diode, the blue host in the single-layered blue emitting material layer B EML has generally electron mobility μe faster than hole mobility uh. In this case, blue emission is reduced because the blue luminous efficiency is too low. Therefore, there is limitation for acting as a red-blue junction diode.

FIG. 5 illustrates a schematic diagram showing energy levels of host and charge transporting materials in another comparative organic light emitting diode where a single blue emitting material layer including a blue host with relatively fast hole mobility and a red emitting material layers are disposed adjacently.

Referring to FIG. 5, in a red-blue junction diode, the blue host in the single-layered blue emitting material layer B EML has hole mobility uh faster than electron mobility μe, or has hole mobility uh similar the electron mobility μe. In this case, the HOMO energy level of the blue host with relatively fast hole mobility uh becomes higher. Accordingly, holes can be leaked to the ETL via the B EML and exciton quenching at an interface between the B EML and the ETL can occur. The quenched excitons can degrade the luminous materials and electron transporting materials so that the luminous lifetime of the diode can be lowered.

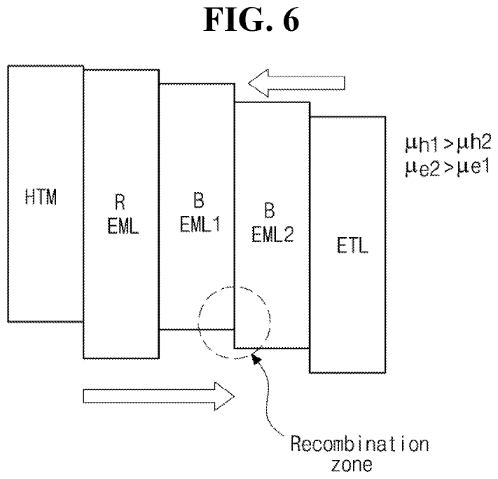

FIG. 6 illustrates a schematic diagram showing energy levels of host and charge transporting materials in an example embodiment organic light emitting diode where two blue emitting material layers each of which includes a blue host with controlled charge mobility and a red emitting material layers are disposed adjacently.

Referring to FIG. 6, as described above, the first blue host 362a in the B-EML1 360A has a hole mobility (μh1) faster than a hole mobility (μh2) of the second blue host 362b in the B-EML2 360B. On the contrary, the second blue host 362b has electron mobility μe2 faster than electron mobility μe1 of the first blue host 362a. Alternatively, the red host 352 in the R-EML 350 can have hole mobility faster than the hole mobility μh1 of the second blue host 362b.

In this case, holes and electrons meets at the interface between the B-EML1 360A and the B-EML2 360B and recombine to form excitons. It is possible to maintain blue luminous efficiency stably as the exciton recombination zone is formed within the EML 340.

It is possible to minimize amounts of non-emissive excitons as the excitons are not lost outside of the emitting material layer. Excitons are not quenched by triplet-triplet annihilation (TTA) and/or triplet-polaron annihilation (TPA). It is possible to minimize the degradation of the luminous materials in the R-EML 350, which is disposed distantly from the interface between two blue emitting material layers B-EML1 360A and B-EML2 360B, by non-emissive excitons because the exciton recombination zone is formed at the interface between the first and second blue emitting material layers B-EML1 360A and B-EML2 360B.

In addition, the B-EML2 360B including the second blue host 362b with relatively low HOMO energy level prevents holes from leaking to the ETL 380. Exciton quenching at an interface between the EML 340 and the ETL 380 is minimized so that the driving voltage of the OLED D1 can be lowered.

The OLED D1 can maintain blue luminous efficiency stably with securing red luminous lifetime stably. The blue and red luminous efficiency can be maintained stably and stable red luminous lifetime can be secured.

The first blue host 362a with relatively excellent hole mobility can include a pyrene-based organic compound. As an example, the first blue host 362a can include an organic compound having the following structure of Chemical Formula 1:

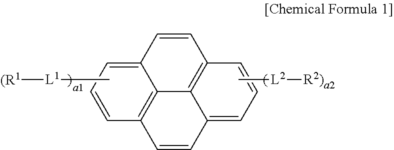

wherein, in Chemical Formula 1,
each of R¹ and R² is independently an unsubstituted or substituted C₆-C₃₀ aryl group or an unsubstituted or substituted C₃-C₃₀ hetero aryl group;
each of L¹ and L² is independently a single bond, an unsubstituted or substituted C₆-C₃₀ arylene group or an unsubstituted or substituted C₃-C₃₀ hetero arylene group; and
each of a1 and a2 is independently 1, 2 or 3, where each R¹-L¹- is identical to or different from each other when a1 is 2 or 3 and each R²-L²- is identical to or different from each other when a2 is 2 or 3.

As used herein, the term “unsubstituted” means that hydrogen is directly linked to a carbon atom. “Hydrogen”, as used herein, can refer to protium, deuterium and tritium.

As used herein, “substituted” means that the hydrogen is replaced with a substituent. The substituent can comprise, but is not limited to, an unsubstituted or halogen-substituted C₁-C₂₀ alkyl group, an unsubstituted or halogen-substituted C₁-C₂₀ alkoxy, halogen, a cyano group, a hydroxyl group, a carboxylic group, a carbonyl group, an amino group, a C₁-C₁₀ alkyl amino group, a C₆-C₃₀ aryl amino group, a C₃-C₃₀ hetero aryl amino group, a nitro group, a hydrazyl group, a sulfonate group, a C₁-C₁₀ alkyl silyl group, a C₁-C₁₀ alkoxy silyl group, a C₃-C₂₀ cyclo alkyl silyl group, a C₆-C₃₀ aryl silyl group, a C₃-C₃₀ hetero aryl silyl group, an unsubstituted or substituted C₆-C₃₀ aryl group, an unsubstituted or substituted C₃-C₃₀ hetero aryl group.

As used herein, the term “hetero” in terms such as “a hetero aryl group”, and “a hetero arylene group” and the like preferably means that at least one carbon atom, for example 1 to 5 carbons atoms, constituting an aliphatic chain, an alicyclic group or ring or an aromatic group or ring is substituted with at least one hetero atom selected from the group consisting of N, O, S and P.

The aryl group can independently include, but is not limited to, an unfused or fused aryl group such as phenyl, biphenyl, terphenyl, naphthyl, anthracenyl, pentalenyl, indenyl, indeno-indenyl, heptalenyl, biphenylenyl, indacenyl, phenalenyl, phenanthrenyl, benzo-phenanthrenyl, dibenzo-phenanthrenyl, azulenyl, pyrenyl, fluoranthenyl, triphenylenyl, chrysenyl, tetraphenylenyl, tetracenyl, pleiadenyl, picenyl, pentaphenylenyl, pentacenyl, fluorenyl, indeno-fluorenyl or spiro-fluorenyl.

The hetero aryl group can independently include, but is not limited to, an unfused or fused hetero aryl group such as pyrrolyl, pyridinyl, pyrimidinyl, pyrazinyl, pyridazinyl, triazinyl, tetrazinyl, imidazolyl, pyrazolyl, indolyl, iso-indolyl, indazolyl, indolizinyl, pyrrolizinyl, carbazolyl, benzo-carbazolyl, dibenzo-carbazolyl, indolo-carbazolyl, indeno-carbazolyl, benzo-furo-carbazolyl, benzo-thieno-carbazolyl, carbolinyl, quinolinyl, iso-quinolinyl, phthlazinyl, quinoxalinyl, cinnolinyl, quinazolinyl, quinolizinyl, purinyl, benzo-quinolinyl, benzo-iso-quinolinyl, benzo-quinazolinyl, benzo-quinoxalinyl, acridinyl, phenazinyl, phenoxazinyl, phenothiazinyl, phenanthrolinyl, perimidinyl, phenanthridinyl, pteridinyl, naphthyridinyl, furanyl, pyranyl, oxazinyl, oxazolyl, oxadiazolyl, triazolyl, dioxinyl, benzo-furanyl, dibenzo-furanyl, thiopyranyl, xanthenyl, chromenyl, iso-chromenyl, thioazinyl, thiophenyl, benzo-thiophenyl, dibenzo-thiophenyl, difuro-pyrazinyl, benzofuro-dibenzo-furanyl, benzothieno-benzo-thiophenyl, benzothieno-dibenzo-thiophenyl, benzothieno-benzo-furanyl, benzothieno-dibenzo-furanyl, xanthene-linked spiro acridinyl, dihydroacridinyl substituted with at least one C₁-C₁₀ alkyl and N-substituted spiro fluorenyl.

As an example, each of the aromatic group (or aryl group) or the hetero aromatic group (or hetero aryl group) can consist of one to four aromatic and/or hetero aromatic rings. When the number of the aromatic and/or hetero aromatic rings of the aryl group and/or the hetero aryl group becomes more than four, conjugated structure among the within the whole molecule becomes too long, thus, the organometallic compound can have too narrow energy bandgap. For example, each of the aryl group or the hetero aryl group can comprise independently, but is not limited to, phenyl, biphenyl, naphthyl, anthracenyl, pyrrolyl, triazinyl, imidazolyl, pyrazolyl, pyridinyl, pyrazinyl, pyrimidinyl, pyridazinyl, furanyl, benzo-furanyl, dibenzo-furanyl, thiophenyl, benzo-thiophenyl, dibenzo-thiophenyl, carbazolyl, acridinyl, carbolinyl, phenazinyl, phenoxazinyl, or phenothiazinyl.

As an example, R¹ in Chemical Formula 1 can be an unsubstituted or substituted C₈-C₂₀ fused hetero aryl group such as a dibenzofuranyl group and/or a dibenzothiophenyl group each of which can be independently unsubstituted or substituted. Alternatively, R² in Chemical Formula 1 can be an unsubstituted or substituted C₈-C₂₀ fused aryl group such as a naphthyl group and/or an anthracenyl group each of which can be independently unsubstituted or substituted. For example, each of the aryl group and the hetero aryl group in R¹ and/or R² can be independently unsubstituted or substituted with at least one group of C₁-C₁₀ alkyl, C₆-C₃₀ aryl (e.g., phenyl) and C₃-C₃₀ hetero aryl.

In another example embodiment, the aryl group and the hetero aryl group (e.g., dibenzofuranyl group and/or dibenzothiophenyl group) of R¹ in Chemical Formula 1 can be linked to, but is not limited to, position 7 (e.g., a1 is 1), or positions 6 and 8 (e.g., a1 is 2) of the pyrene core. In another example embodiment, the aryl group (e.g., naphthyl group and/or anthracenyl group) of R² in Chemical Formula 1 can be linked to, but is not limited to, position 2 or position 3 (e.g., a2 is 1), or positions 1 and 3 (e.g., a2 is 2) of the pyrene core. As an example, R² in Chemical Formula 1 can be a naphthyl group unsubstituted or substituted with at least one C₆-C₂₀ aryl group (e.g., phenyl). The naphthyl group can be 1-naphthyl group or 2-naphthyl group and the at least one C₆-C₂₀ aryl group can be substituted to a benzene ring of the naphthyl group not linked to the pyrene core. In some embodiments, when a1 is 2 or 3, the (R¹)ₐ₁-L¹-moieties are the same. In some embodiments, when a2 is 2 or 3, the (R²)ₐ₂-L²- moieties are the same. In another embodiment, when a1 is 2 or 3, and the (R¹)ₐ₁-L¹- moieties are different, and at least one (R¹)ₐ₁-L¹- moiety is a phenyl group. In another embodiment, when a2 is 2 or 3, and the (R²)ₐ₂-L²- moieties are different, at least one (R²)ₐ₂-L²- moiety is a phenyl group.

In one example embodiment, the first blue host 362a can have the hole mobility between about 1.0E-08 cm²/(V·s) and about 1.0E-4 cm²/(V·s), for example, about 1.0E-7 cm²/(V·s) and about 1.0E-5 cm²/(V·s), and the electron mobility between about 1.0E-7 cm²/(V·s) and about 1.0E-3 cm²/(V·s), for example, about 1.0E-06 cm²/(V·s) and about 1.0E-4 cm²/(V·s), but is not limited thereto.

More particularly, the first blue host 362a can be, but is not limited to, at least one of organic compounds having the following structure of Chemical Formula 2:

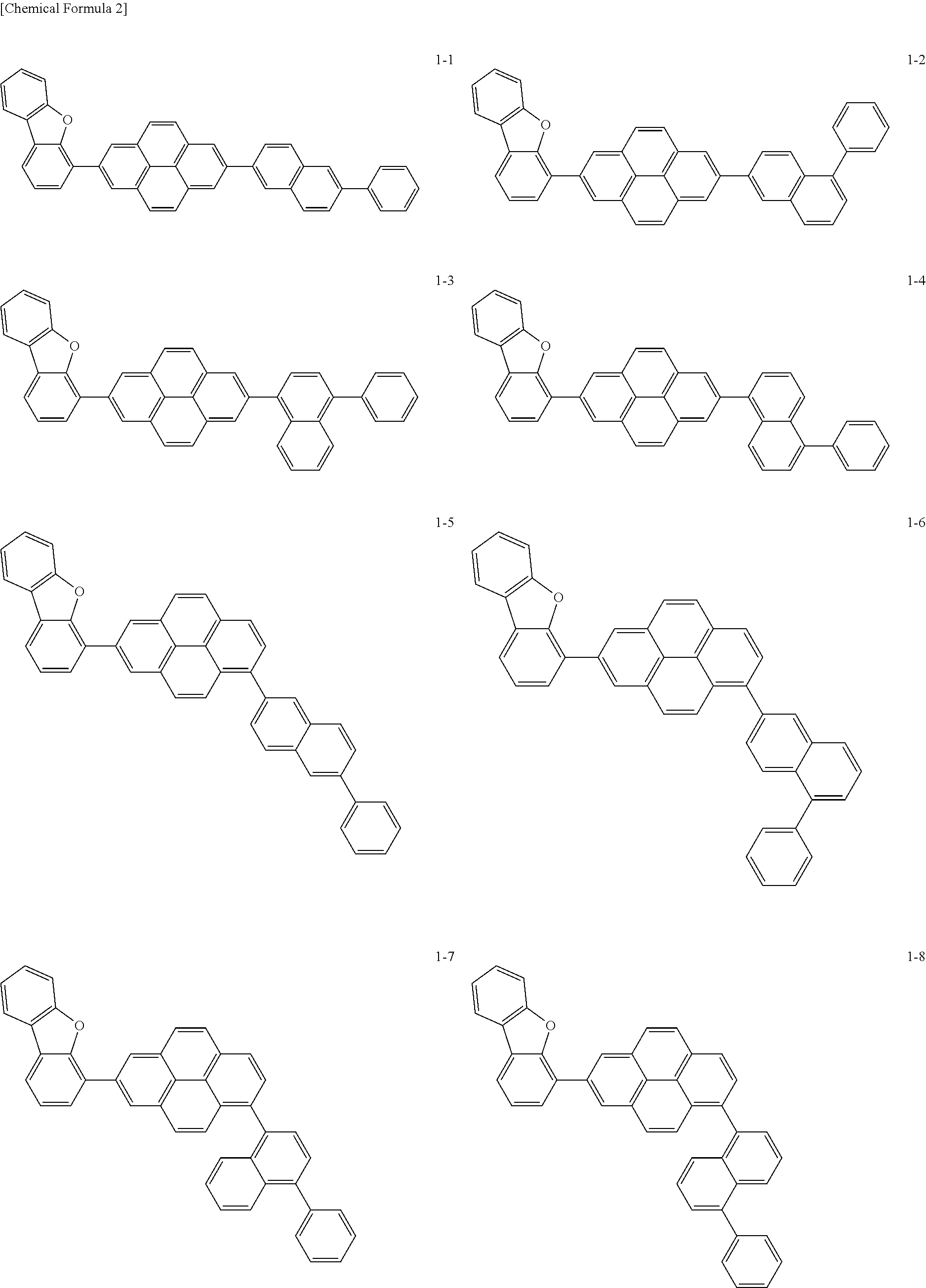

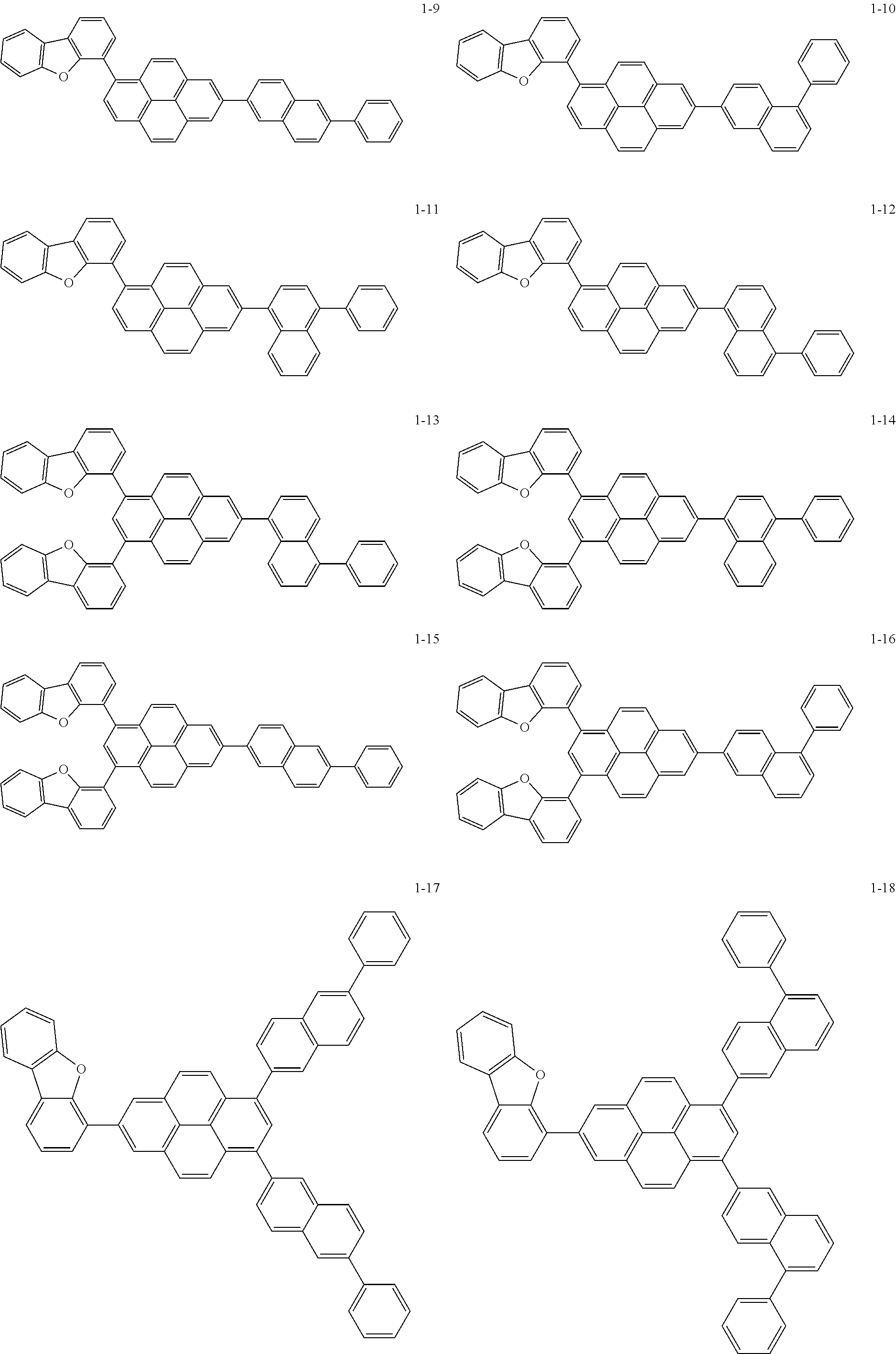

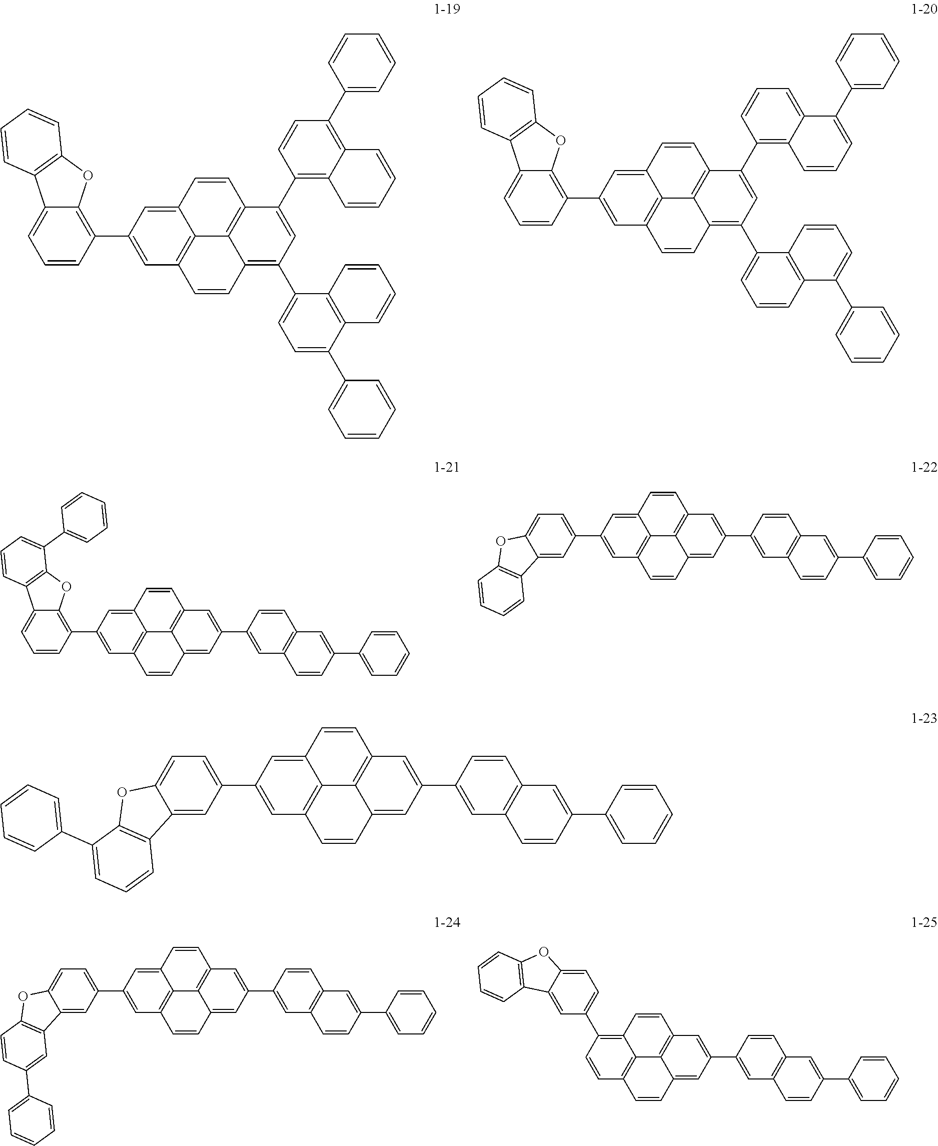

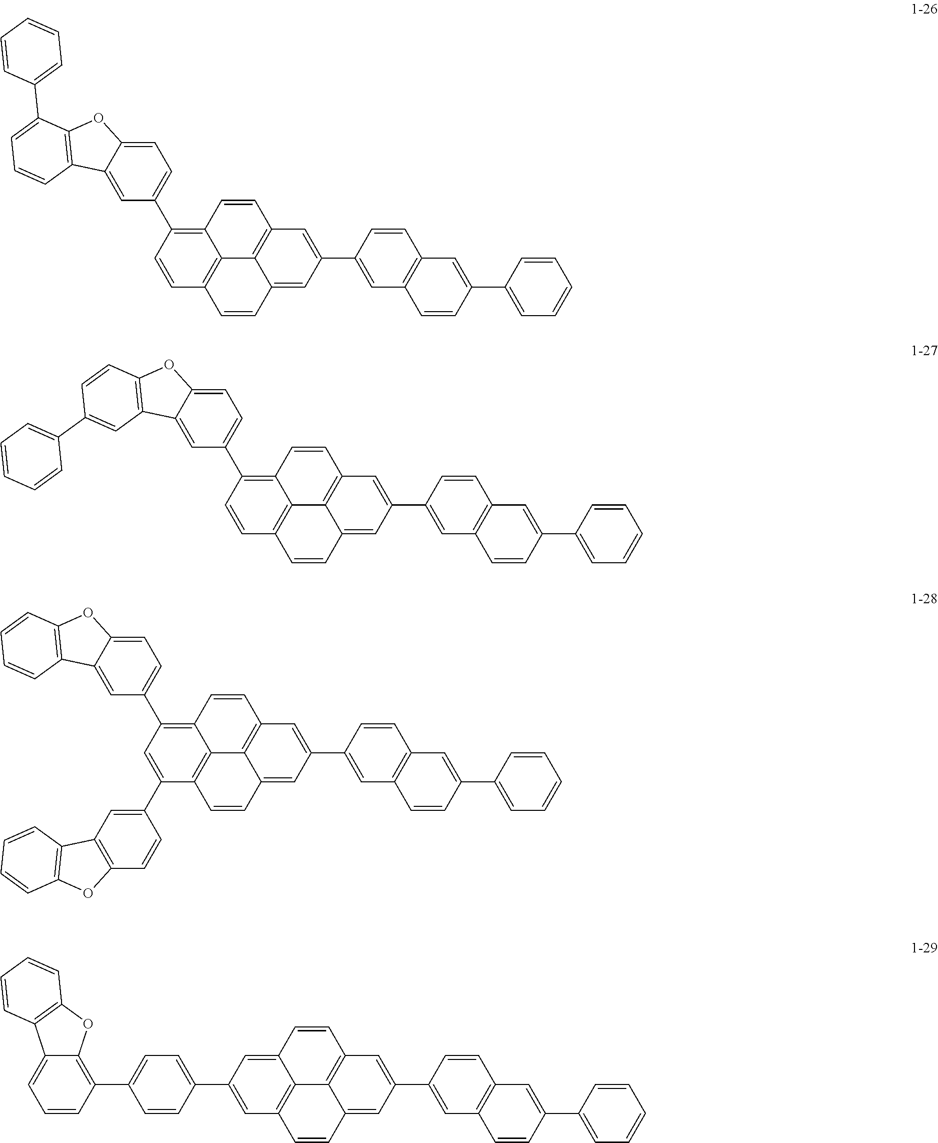 [SMILES: c1ccc(-c2ccc3cc(-c4cc5ccc6ccc(-c7ccc8oc9c(-c%10ccccc%10)cccc9c8c7)c7ccc(c4)c5c67)ccc3c2)cc1 ; c1ccc(-c2ccc3cc(-c4cc5ccc6ccc(-c7ccc8oc9ccc(-c%10ccccc%10)cc9c8c7)c7ccc(c4)c5c67)ccc3c2)cc1 ; c1ccc(-c2ccc3cc(-c4cc5ccc6c(-c7ccc8oc9ccccc9c8c7)cc(-c7ccc8oc9ccccc9c8c7)c7ccc(c4)c5c67)ccc3c2)cc1 ; c1ccc(-c2ccc3cc(-c4cc5ccc6cc(-c7ccc(-c8cccc9c8oc8ccccc89)cc7)cc7ccc(c4)c5c67)ccc3c2)cc1]

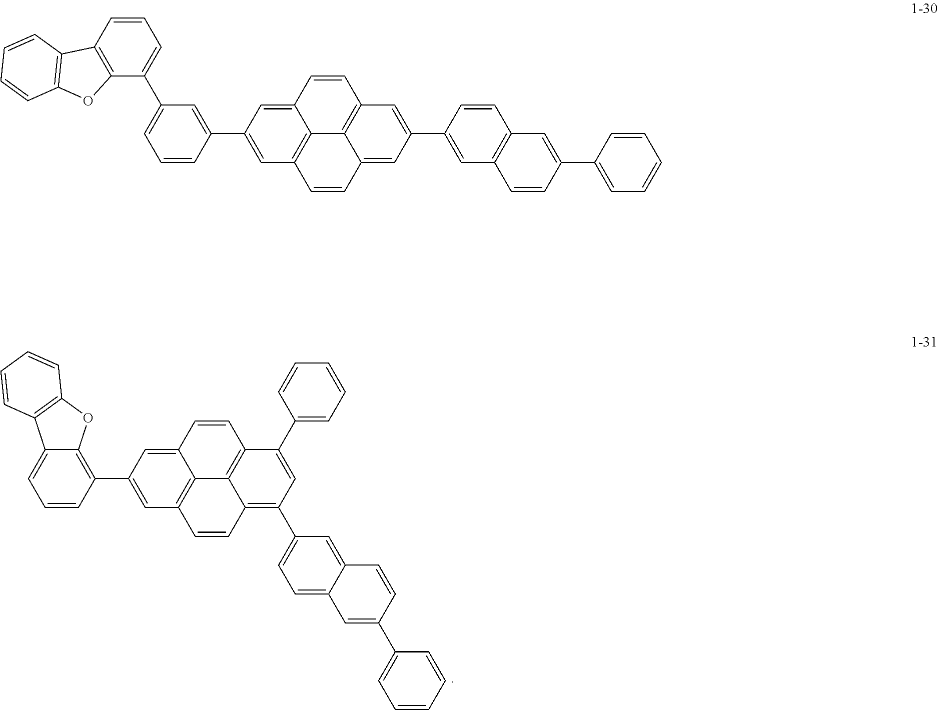 [SMILES: c1ccc(-c2ccc3cc(-c4cc5ccc6cc(-c7cccc(-c8cccc9c8oc8ccccc89)c7)cc7ccc(c4)c5c67)ccc3c2)cc1 ; c1ccc(-c2ccc3cc(-c4cc(-c5ccccc5)c5ccc6cc(-c7cccc8c7oc7ccccc78)cc7ccc4c5c67)ccc3c2)cc1]

The second blue host 362b can be an anthracene-based organic compound. For example, the second blue host 362b can include an organic compound having the following structure of Chemical Formula 3:

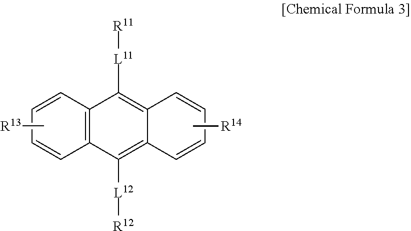

wherein, in Chemical Formula 3,
each of R¹¹ and R¹² is independently an unsubstituted or substituted C₆-C₃₀ aryl group or an unsubstituted or substituted C₃-C₃₀ hetero aryl group;
each of R¹³ and R¹⁴ is independently hydrogen, an unsubstituted or substituted C₁-C₂₀ alkyl group, an unsubstituted or substituted C₆-C₃₀ aryl group or an unsubstituted or substituted C₃-C₃₀ hetero aryl group; and
L¹¹ and L¹² is independently a single bond, an unsubstituted or substituted C₆-C₃₀ arylene group or an unsubstituted or substituted C₃-C₃₀ hetero arylene group.

More particularly, the second blue host 362b can be selected from, but is not limited to, the group consisting of 9,10-di(naphthalen-2-yl)anthracene, 2-methyl-9,10-bis(naphthalen-2-yl)anthracene, 2-tert-Butyl-9,10-di(naphthen-2-yl)anthracene, 9,10-di(naphthalen-2-yl)-2-phenylanthracene, 9-phenyl-10-(p-tolyl)anthracene, 9-(1-naphthyl)-10-(p-tolyl)anthracene, 9-(2-naphthyl)-10-(p-tolyl)anthracene, 2-(3-(10-phenylanthracen-9-yl)-phenyl)dibenzo[b,d]furan, 2-(4-(10-phenylanthracen-9-yl)phenyl)dibenzo[b,d]furan and combinations thereof

In one example embodiment, the second blue host 362b can have the hole mobility between about 1.0E-11 cm²/(V·s) and about 1.0E-7 cm²/(V·s), for example, about 1.0E-10 cm²/(V·s) and about 1.0E-8 cm²/(V·s), and the electron mobility between about 1.0E-6 cm²/(V·s) and about 1.0E-2 cm²/(V·s), for example, about 1.0E-05 cm²/(V·s) and about 1.0E-3 cm²/(V·s), but is not limited thereto.

Each of the first blue emitter 364a and the second blue emitter 364b can independently include at least one of a blue phosphorescent material, a blue fluorescent material and a blue delayed fluorescent material, for example, can be the blue fluorescent material. The first blue emitter 364a can be identical to or different form the second blue emitter 364b.

For example, each of the first blue emitter 364a and the second blue emitter 364b can independently include, but is not limited to, perylene, 4,4′-Bis[4-(di-p-tolylamino)styryl]biphenyl (DPAVBi), 4-(Di-p-tolylamino)-4-4′-[(di-p-tolylamino)styryl]stilbene (DPAVB), 4,4′-Bis[4-(diphenylamino)styryl]biphenyl (BDAVBi), 2,7-Bis(4-diphenylamino)styryl)-9,9-spirofluorene (spiro-DPVBi), [1,4-bis[2-[4-[N,N-di(p-tolyl)amino]phenyl]vinyl]benzene (DSB), 1-4-di-[4-(N,N-diphenyl)amino]styryl-benzene (DSA), 2,5,8,11-Tetra-tetr-butylperylene (TBPe), Bis(2-hydroxylphenyl)-pyridine)beryllium (Bepp2), 9-(9-Phenylcarbazol-3-yl)-10-(naphthalen-1-yl)anthracene (PCAN), mer-Tris(1-phenyl-3-methylimidazolin-2-ylidene-C,C(2)′iridium(III) (mer-Ir(pmi)₃), fac-Tris(1,3-diphenyl-benzimidazolin-2-ylidene-C,C(2)′iridium(III) (fac-Ir(dpbic)₃), Bis(3,4,5-trifluoro-2-(2-pyridyl)phenyl-(2-carboxypyridyl)iridium(III) ((Ir(tfpd)₂pic), tris(2-(4,6-difluorophenyl)pyridine))iridium(III) ((Ir(Fppy)₃), Bis[2-(4,6-difluorophenyl)pyridinato-C₂,N](picolinato)iridium(III) (FIrpic), DABNA-1, DABNA-2, t-DABNA, v-DABNA and/or combinations thereof.

The contents of the first blue host 362a and the second blue host 362b in the B-EML1 360A and the B-EML2 360B can be about 50 wt % to about 99 wt %, for example, about 80 wt % to about 95 wt %, and the contents of the first blue emitter 364a and the second blue emitter 364b in the B-EML1 360A and the B-EML2 360B can be about 1 wt % to about 50 wt %, for example, about 5 wt % to about 20 wt %, but is not limited thereto. When each of the B-EML1 360A and the B-EML2 360B includes a P-type blue host and an N-type blue host, the P-type blue host and the N-type blue host in the B-EML1 360A and the B-EML2 360B can be admixed, but is not limited to, with a weight ratio of about 4:1 to about 1:4, for example about 3:1 to about 1:3.

Referring back to FIG. 3, the HIL 310 is disposed between the first electrode 210 and the HTL 320 and can improve an interface property between the inorganic first electrode 210 and the organic HTL 320. In one example embodiment, the HIL 310 can include, but is not limited to, 4,4′,4″-Tris(3-methylphenylamino)triphenylamine (MTDATA), 4,4′,4″-Tris(N,N-diphenyl-amino)triphenylamine (NATA), 4,4′,4″-Tris(N-(naphthalene-1-yl)-N-phenyl-amino)triphenylamine (1T-NATA), 4,4′,4″-Tris(N-(naphthalene-2-yl)-N-phenyl-amino)triphenylamine (2T-NATA), Copper phthalocyanine (CuPc), Tris(4-carbazoyl-9-yl-phenyl)amine (TCTA), N,N′-Diphenyl-N,N′-bis(1-naphthyl)-1,1′-biphenyl-4,4″-diamine (NPB; NPD), N,N′-Bis{4-[bis(3-methylphenyl)amino]phenyl}-N,N′-diphenyl-4,4′-biphenyldiamine (DNTPD). 1,4,5,8,9,11-Hexaazatriphenylenehexacarbonitrile (Dipyrazino[2,3-f:2′3′-h]quinoxaline-2,3,6,7,10,11-hexacarbonitrile; HAT-CN), 2,3,5,6-tetrafluoro-7,7,8,8-tetracyanoquinodimethane (F4-TCNQ), 1,3,4,5,7,8-hexafluorotetracyanonaphthoquinodimethane (F6-TCNNQ), 1,3,5-tris[4-(diphenylamino)phenyl]benzene (TDAPB), poly(3,4-ethylenedioxythiphene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine, N,N′-diphenyl-N,N′-di[4-(N,N′-diphenyl-amino)phenyl]benzidine (NPNPB), TAPC, the compound of following Chemical Formula 4 and/or combinations thereof.

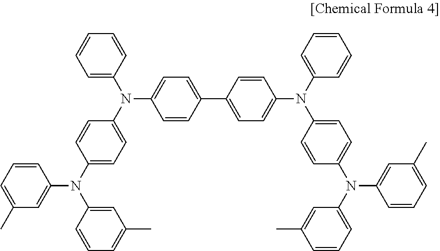 [SMILES: Cc1cccc(N(c2ccc(N(c3ccccc3)c3ccc(-c4ccc(N(c5ccccc5)c5ccc(N(c6cccc(C)c6)c6cccc(C)c6)cc5)cc4)cc3)cc2)c2cccc(C)c2)c1]

In an alternative embodiment, the HIL 310 can include a hole transporting material below doped with the above hole injecting material (e.g., HAT-CN, F4-TCNQ, F6-TCNNQ) The contents of the hole injecting material in the HIL 310 can be, but is not limited to, about 2 wt. % to about 15 wt %. In certain embodiments, the HIL 310 can be omitted in compliance of the OLED D1 property.

The HTL 320 is disposed between the first electrode 210 and the EML 340. In one example embodiment, the HTL 320 can include, but is not limited to, N,N′-Diphenyl-N,N′-bis(3-methylphenyl)-1,1′-biphenyl-4,4′-diamine (TPD), NPB(NPD), 4,4′-bis(N-carbazolyl)-1,1′-biphenyl (CBP), DNTPD, BPBPA), Poly[N,N′-bis(4-butylphenyl)-N,N′-bis(phenyl)-benzidine] (Poly-TPD), Poly[(9,9-dioctylfluorenyl-2,7-diyl)-co-(4,4′-(N-(4-sec-butylphenyl)diphenylamine))] (TFB), TAPC, 3,5-Di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine), N-([1,1′-Biphenyl]-4-yl)-9,9-dimethyl-N-(4-(9-phenl-9H-carbazol-3-yl)phenyl)-9H-fluoren-2-amine, and/or combinations thereof.

The ETL 380 and the EIL 390 can be laminated sequentially between the EML 340 and the second electrode 220. An electron transporting material included in the ETL 380 has high electron mobility so as to provide electrons stably with the EML 340 by fast electron transportation.

In one example embodiment, the ETL 380 can include at least one of an oxadiazole-based compound, a triazole-based compound, a phenanthroline-based compound, a benzoxazole-based compound, a benzothiazole-based compound, a benzimidazole-based compound, and a triazine-based compound.

For example, the ETL 380 can include, but is not limited to, tris-(8-hydroxyquinoline aluminum (Alq₃), 2-biphenyl-4-yl-5-(4-t-butylphenyl)-1,3,4-oxadiazole (PBD), spiro-PBD, lithium quinolate (Liq), 2,2′,2″-(1,3,5-benzenetriyl)-tris(1-phenyl-1-H-benzimidazole (TPBi), Bis(2-methyl-8-quinolinolato-N1,O8)-(1,1′-biphenyl-4-olato)aluminum (BAlq), 4,7-diphenyl-1,10-phenanthroline (Bphen), 2,9-Bis(naphthalene-2-yl)4,7-diphenyl-1,10-phenanthroline (NBphen), 2,9-Dimethyl-4,7-diphenyl-1,10-phenathroline (BCP), 3-(4-Biphenyl)-4-phenyl-5-tert-butylphenyl-1,2,4-triazole (TAZ), 4-(Naphthalen-1-yl)-3,5-diphenyl-4H-1,2,4-triazole (NTAZ), 1,3,5-Tri(p-pyrid-3-yl-phenyl)benzene (TpPyPB), 2,4,6-Tris(3′-(pyridin-3-yl)biphenyl-3-yl)1,3,5-triazine (TmPPPyTz), Poly[9,9-bis(3′-((N,N-dimethyl)-N-ethylammonium)-propyl)-2,7-fluorene]-alt-2,7-(9,9-dioctylfluorene)] (PFNBr), tris(phenylquinoxaline) (TPQ), TSPO1,2-[4-(9,10-Di-naphthalen-2-yl-anthracen-2-yl)phenyl]-1-phenyl-1H-benzimidazole (ZADN) and/or combinations thereof.

The EIL 390 is disposed between the second electrode 220 and the ETL 380, and can improve physical properties of the second electrode 220 and therefore, can enhance the lifespan of the OLED D1. In one example embodiment, the EIL 390 can include, but is not limited to, an alkali metal halide and/or an alkaline earth metal halide such as LiF, CsF, NaF, BaF₂ and the like, and/or an organometallic compound such as Liq, lithium benzoate, sodium stearate, and the like.

Alternatively, the ETL 380 and the EIL 390 can have a single layer where the electron transporting material and/or the electron injecting material are admixed. As an example, the electron transport/electron injection layer can have two different electron transporting materials. Two different electron transporting materials in the electron transport/electron injection layer can be admixed with, but is not limited to, a weight ratio of about 3:7 to about 7:3.

When holes are transferred to the second electrode 220 via the EML 340 and/or electrons are transferred to the first electrode 210 via the EML 340, the OLED D1 can have short lifespan and reduced luminous efficiency. In order to prevent or minimize those phenomena, the OLED D1 in accordance with this aspect of the present disclosure can have at least one exciton blocking layer adjacent to the EML 340.

As an example, the OLED D1 can include the EBL 330 between the HTL 320 and the EML 340 so as to control and prevent electron transfers. In one example embodiment, the EBL 330 can include, but is not limited to, TCTA, Tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, 1,3-Bis(carbazol-9-yl)benzene (mCP), 3,3-Di(9H-carbazol-9-yl)biphenyl (mCBP), CuPc, DNTPD, TDAPB, DCDPA, 2,8-bis(9-phenyl-9H-carbazol-3-yl)dibenzo[b,d]thiophene and/or combinations thereof.

In addition, the OLED D1 can further include the HBL 370 as a second exciton blocking layer between the EML 340 and the ETL 380 so that holes cannot be transferred from the EML 340 to the ETL 380. In one example embodiment, the HBL 370 can include, but is not limited to, at least one of an oxadiazole-based compound, a triazole-based compound, a phenanthroline-based compound, a benzoxazole-based compound, a benzothiazole-based compound, a benzimidazole-based compound, and a triazine-based compound.

For example, the HBL 370 can include a material having a relatively low HOMO energy level compared to the luminescent materials in EML 340. The HBL 350 can include, but is not limited to, BCP, BAlq, Alq₃, PBD, spiro-PBD, Liq, Bis-4,5-(3,5-di-3-pyridylphenyl)-2-methylpyrimidine (B3PYMPM), Bis[2-(diphenylphosphino)phenyl]ether oxide (DPEPO), 9-(6-(9H-carbazol-9-yl)pyridine-3-yl)-9H-3,9′-bicarbazole, TSPO1 and/or combinations thereof. In certain embodiments, the EBL 330 and/or the HBL 370 can be omitted.

Two blue emitting material layers (B-EML1 and B-EML2) 360A and 360B are disposed adjacently to the red emitting material layer 350, and each of the B-EML1 360A and the B-EML2 360B includes the first blue host 362a and the second blue host 362b, respectively, each of which has controlled charge mobility and/or energy levels. Stable blue luminous efficiency can be maintained as the exciton recombination zone is formed within the EML 340. Stable red luminous lifespan can be secured and the driving voltage of the OLED D1 cannot be raised by preventing exciton quenching.

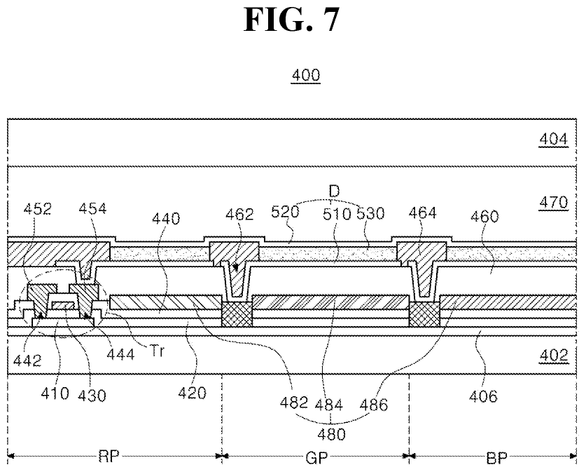

In another example embodiment, an organic light emitting display device can implement full-color including white color. FIG. 7 illustrates a schematic cross-sectional view of an organic light emitting display device in accordance with another example embodiment of the present disclosure.

As illustrated in FIG. 7, an organic light emitting display device 400 comprises a first substrate 402 that defines each of a red pixel region RP, a green pixel region GP and a blue pixel region BP, a second substrate 404 facing the first substrate 402, a thin film transistor Tr on the first substrate 402, an OLED D disposed between the first and second substrates 402 and 404 and emitting white (W) light and a color filter layer 480 disposed between the OLED D and the first substrate 402.

Each of the first and second substrates 402 and 404 can include, but is not limited to, glass, flexible material and/or polymer plastics. For example, each of the first and second substrates 402 and 404 can be made of PI, PES, PEN, PET, PC and/or combinations thereof. The first substrate 402, on which a thin film transistor Tr and the OLED D are arranged, forms an array substrate. In certain embodiments, the second substrate 404 can be omitted.

A buffer layer 406 can be disposed on the first substrate 402. The thin film transistor Tris disposed on the buffer layer 406 correspondingly to each of the red pixel region RP, the green pixel region GP and the blue pixel region BP. In certain embodiments, the buffer layer 406 can be omitted.

A semiconductor layer 410 is disposed on the buffer layer 406. The semiconductor layer 410 can be made of or include oxide semiconductor material or polycrystalline silicon.

A gate insulating layer 420 including an insulating material, for example, inorganic insulating material such as silicon oxide (SiOₓ, wherein 0<x≤2) or silicon nitride (SiNₓ, wherein 0<x≤2) is disposed on the semiconductor layer 410.

A gate electrode 430 made of a conductive material such as a metal is disposed over the gate insulating layer 420 so as to correspond to a center of the semiconductor layer 410. An interlayer insulating layer 440 including an insulating material, for example, inorganic insulating material such as SiOₓ or SiNₓ, or an organic insulating material such as benzocyclobutene or photo-acryl, is disposed on the gate electrode 430.

The interlayer insulating layer 440 has first and second semiconductor layer contact holes 442 and 444 that expose or do not cover a portion of the surface nearer to the opposing ends than to a center of the semiconductor layer 410. The first and second semiconductor layer contact holes 442 and 444 are disposed on opposite sides of the gate electrode 430 with spacing apart from the gate electrode 430.

A source electrode 452 and a drain electrode 454, which are made of or include a conductive material such as a metal, are disposed on the interlayer insulating layer 440. The source electrode 452 and the drain electrode 454 are spaced apart from each other with respect to the gate electrode 430. The source electrode 452 and the drain electrode 454 contact both sides of the semiconductor layer 410 through the first and second semiconductor layer contact holes 442 and 444, respectively.

The semiconductor layer 410, the gate electrode 430, the source electrode 452 and the drain electrode 454 constitute the thin film transistor Tr, which acts as a driving element.

In FIG. 7, the gate line GL and the data line DL, which cross each other to define the pixel region P, and a switching element Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL, and the thin film transistor Tr can further include the storage capacitor Cst configured to constantly keep a voltage of the gate electrode 430 for one frame.

A passivation layer 460 is disposed on the source electrode 452 and the drain electrode 454 and covers the thin film transistor Tr over the entire first substrate 402. The passivation layer 460 has a drain contact hole 462 that exposes or does not cover the drain electrode 454 of the thin film transistor Tr.

The OLED D is located on the passivation layer 460. The OLED D includes a first electrode 510 that is connected to the drain electrode 454 of the thin film transistor Tr, a second electrode 520 facing the first electrode 510 and an emissive layer 530 disposed between the first and second electrodes 510 and 520.

The first electrode 510 formed for each pixel region RP, GP or BP can be an anode and can include a conductive material having relatively high work function value. For example, the first electrode 510 can include, but is not limited to, ITO, IZO, ITZO, SnO, ZnO, ICO, AZO, and/or combinations thereof. Alternatively, a reflective electrode or a reflective layer can be disposed under the first electrode 510. For example, the reflective electrode or the reflective layer can include, but is not limited to, Ag or APC alloy.

A bank layer 464 is disposed on the passivation layer 460 in order to cover edges of the first electrode 510. The bank layer 464 exposes or does not cover a center of the first electrode 510 corresponding to each of the red pixel RP, the green pixel GP and the blue pixel BP. In certain embodiments, the bank layer 464 can be omitted.

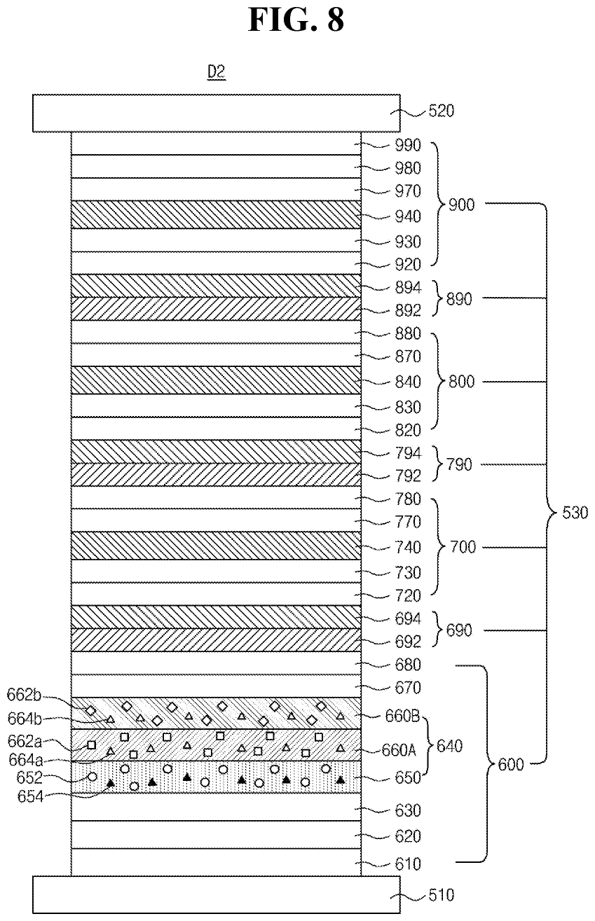

An emissive layer 530 that can include multiple emitting parts is disposed on the first electrode 510. As illustrated in FIG. 8, the emissive layer 530 can include multiple emitting parts 600, 700, 800 and 900, and at least one charge generation layer 690, 790 and 890. Each of the emitting parts 600, 700, 800 and 900 can include at least one emitting material layer and can further include an HIL, an HTL, an EBL, an HBL, an ETL and/or an EIL.

The second electrode 520 can be disposed on the first substrate 402 above which the emissive layer 530 can be disposed. The second electrode 520 can be disposed over the entire display area, can include a conductive material with a relatively low work function value compared to the first electrode 510, and can be a cathode. For example, the second electrode 520 can include, but is not limited to, highly reflective material such as Al, Mg, Ca, Ag, alloy thereof, and/or combinations thereof such as Al—Mg.

Returning to FIG. 7, the color filter layer 480 can be disposed between the first substrate 402 and the OLED D, for example, between the interlayer insulating layer 440 and the passivation layer 460. The color filter layer 480 can includes a red color filter pattern 482, a green color filter pattern 484 and a blue color filter pattern 486 each of which is disposed correspondingly to the red pixel RP, the green pixel GP and the blue pixel BP, respectively.

In addition, an encapsulation film 470 can be disposed on the second electrode 520 in order to prevent or reduce outer moisture from penetrating into the OLED D. The encapsulation film 470 can have, but is not limited to, a laminated structure including a first inorganic insulating film, an organic insulating film and a second inorganic insulating film (170 in FIG. 2). In addition, a polarizing plate can be attached onto the second substrate 404 to reduce reflection of external light. For example, the polarizing plate can be a circular polarizing plate.

In FIG. 7, the light emitted from the OLED D passes through the first electrode 510 and the color filter layer 480 is disposed under the OLED D. The organic light emitting display device 400 can be a bottom emission type. Alternatively, when the organic light emitting display device 400 is a top-emission type, the light emitted from the OLED can pass through the second electrode 520 and the color filter layer can be disposed on the OLED D. In this case, the color filter layer 480 can be attached to the OLED D through an adhesive layer, or can be disposed directly on the OLED D.

In addition, a color conversion layer can be formed or disposed between the OLED D and the color filter layer 480. The color conversion layer can include a red color conversion layer, a green color conversion layer and a blue color conversion layer each of which is disposed correspondingly to each pixel (RP, GP and BP), respectively, so as to convert the white (W) color light to each of a red, green and blue color lights, respectively. Alternatively, the organic light emitting display device 400 can comprise the color conversion layer instead of the color filter layer 480.

As described above, the white (W) color light emitted from the OLED D can be transmitted through the red color filter pattern 482, the green color filter pattern 484 and the blue color filter pattern 486 each of which is disposed correspondingly to the red pixel region RP, the green pixel region GP and the blue pixel region BP, respectively, so that red, green and blue color lights are displayed in the red pixel region RP, the green pixel region GP and the blue pixel region BP.

An OLED that can be applied into the organic light emitting display device will be described in more detail. FIG. 8 illustrates a schematic cross-sectional view of an organic light emitting diode having a tandem structure of two emitting parts.

As illustrated in FIG. 8, the OLED D2 in accordance with the example embodiment of the present disclosure includes first and second electrodes 510 and 520 and an emissive layer 530 disposed between the first and second electrodes 510 and 520. The emissive layer 530 includes a first emitting part 600 disposed between the first electrode 510 and the second electrode 520, a second emitting part 700 disposed between the first emitting part 600 and the second electrode 520, a third emitting part 800 disposed between the second emitting part 700 and the second electrode 520, a fourth emitting part 900 disposed between the third emitting part 800 and the second electrode 520, a first charge generation layer (CGL1) 690 disposed between the first emitting part 600 and the second emitting part 700, a second charge generation layer (CGL2) 790 disposed between the second emitting part 700 and the third emitting part 800, and a third charge generation layer (CGL3) 890 disposed between the third emitting part 800 and the fourth emitting part 900.

The first electrode 510 can be an anode and can include a conductive material having relatively high work function value such as TCO. For example, the first electrode 510 can include, but is not limited to, ITO, IZO, ITZO, SnO, ZnO, ICO, AZO, and/or combinations thereof. The second electrode 520 can be a cathode and can include a conductive material with a relatively low work function value. For example, the second electrode 520 can include, but is not limited to, highly reflective material such as Al, Mg, Ca, Ag, alloy thereof and/or combination thereof such as Al—Mg.

The first emitting part 600 includes a first emitting material layer (EML1) 640. The first emitting part 600 can include at least one of a hole injection layer (HIL) 610 disposed between the first electrode 510 and the EML1 640, a first hole transport layer (HTL1) 620 disposed between the HIL 610 and the EML1 640 and a first electron transport layer (ETL1) 680 disposed between the EML1 640 and the CGL1 690. Alternatively, the first emitting part 600 can further include a first electron blocking layer (EBL1) 630 disposed between the HTL1 620 and the EML1 640 and/or a first hole blocking layer (HBL1) 670 disposed between the EML1 640 and the ETL1 680.

The second emitting part 700 includes a second emitting material layer (EML2) 740. The second emitting part 700 can include at least one of a second hole transport layer (HTL2) 720 disposed between the CGL1 690 and the EML2 740 and a second electron transport layer (ETL2) 780 disposed between the EML2 740 and the CGL2 790. Alternatively, the second emitting part 700 can further include a second electron blocking layer (EBL2) 730 disposed between the HTL2 720 and the EML2 740 and/or a second hole blocking layer (HBL2) 770 disposed between the EML2 740 and the ETL2 780.

The third emitting part 800 includes a third emitting material layer (EML3) 840. The third emitting part 800 can include at least one of a third hole transport layer (HTL3) 820 disposed between the CGL2 790 and the EML3 840 and a third electron transport layer (ETL3) 880 disposed between the EML3 840 and the CGL3 890. Alternatively, the third emitting part 800 can further include a third electron blocking layer (EBL3) 830 disposed between the HTL3 820 and the EML3 840 and/or a third hole blocking layer (HBL3) 870 disposed between the EML3 840 and the ETL3 880.

The fourth emitting part 900 includes a fourth emitting material layer (EML4) 940. The fourth emitting part 900 can include at least one of a fourth hole transport layer (HTL4) 920 disposed between the CGL3 890 and the EML4 940, a fourth electron transport layer (ETL4) 980 disposed between the EML4 940 and the second electrode 520, and an electron injection layer (EIL) 990 disposed between the ETL4 980 and the second electrode 520. Alternatively, the fourth emitting part 900 can further include at least one of a fourth electron blocking layer (EBL4) 930 disposed between the HTL4 920 and the EML4 940 and a fourth hole blocking layer (HBL4) 970 disposed between the EML4 940 and the ETL4 980.

The HIL 610 is disposed between the first electrode 510 and the HTL1 620 and improves an interface property between the inorganic first electrode 510 and the organic HTL1 620. In one embodiment, the HIL 610 can include, but is not limited to, MTDATA, NATA, 1T-NATA, 2T-NATA, CuPc, TCTA, NPB (NPD), DNTPD, HAT-CN, TDAPB, PEDOT/PSS, N-(biphenyl-4-yl)-9,9-dimethyl-N-(4-(9-phenyl-9H-carbazol-3-yl)phenyl)-9H-fluoren-2-amine, NPNPB, TAPC, the compound of Chemical Formula 4 and/or combinations thereof. Alternatively, the HIL 610 can include hole transporting material doped with the hole injecting material. In certain embodiments, the HIL 610 can be omitted in compliance of the OLED D2 property.

In one example embodiment, each of the HTL1 620, the HTL2 720, the HTL3 820 and the HTL4 920 can include, but is not limited to, TPD, NPB (NPD), DNTPD, BPBPA, CBP, Poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, N-([1,1′-Biphenyl]-4-yl)-9,9-dimethyl-N-(4-(9-phenl-9H-carbazol-3-yl)phenyl)-9H-fluoren-2-amine and/or combination thereof.

Each of the ETL1 680, the ETL2 780, the ETL3 880 and the ETL4 980 transports electrons to each of the EML1 640, the EML2 740, the EML3 840 and the EML4 940, respectively. As an example, each of the ETL1 680, the ETL2 780, the ETL3 880 and the ETL4 980 can include at least one of an oxadiazole-based compound, a triazole-based compound, a phenanthroline-based compound, a benzoxazole-based compound, a benzothiazole-based compound, a benzimidazole-based compound and a triazine-based compound. For example, each of the ETL1 680 and the ETL2 780 can include, but is not limited to, Alq₃, PBD, spiro-PBD, Liq, TPBi, BAlq, Bphen, NBphen, BCP, TAZ, NTAZ, TpPyPB, TmPPPyTz, PFNBr, TPQ, TSPO1, ZADN and/or combinations thereof.

The EIL 990 is disposed between the second electrode 520 and the ETL4 980, and can improve physical properties of the second electrode 520 and therefore, can enhance the lifespan of the OLED D2. In one example embodiment, the EIL 990 can include, but is not limited to, an alkali metal halide or an alkaline earth metal halide such as LiF, CsF, NaF, BaF₂ and the like, and/or an organometallic Compound such as Liq, lithium benzoate, sodium stearate, and the like.

Each of the EBL1 630, the EBL2 730, the EBL3 830 and the EBL4 930 can independently include, but is not limited to, TCTA, Tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, mCP, mCBP, CuPc, DNTPD, TDAPB, DCDPA, 2,8-bis(9-phenyl-9H-carbazol-3-yl)dibenzo[b,d]thiophene and/or combinations thereof, respectively.

Each of the HBL1 670, the HBL2 770, the HBL3 870 and the HBL4 970 can include, but is not limited to, at least one of an oxadiazole-based compound, a triazole-based compound, a phenanthroline-based compound, a benzoxazole-based compound, a benzothiazole-based compound, a benzimidazole-based compound, and a triazine-based compound. For example, each of the HBL1 670, the HBL2 770, the HBL3 870 and the HBL4 970 can independently include, but is not limited to, BCP, BAlq, Alq₃, PBD, spiro-PBD, Liq, B3PYMPM, DPEPO, 9-(6-(9H-carbazol-9-yl)pyridine-3-yl)-9H-3,9′-bicarbazole, TSPO1 and/or combinations thereof, respectively.

The CGL1 690 includes a first N-type charge generation layer (N-CGL1) 692 disposed between the ETL1 680 and the HTL2 720 and a first P-type charge generation layer (P-CGL1) 694 disposed between the N-CGL1 692 and the HTL2 720. The CGL2 790 includes a second N-type charge generation layer (N-CGL2) 792 disposed between the ETL2 780 and the HTL3 820 and a second P-type charge generation layer (P-CGL2) 794 disposed between the N-CGL2 792 and the HTL3 820. The CGL3 890 includes a third N-type charge generation layer (N-CGL3) 892 disposed between the ETL3 880 and the HTL4 920 and a third P-type charge generation layer (P-CGL3) 894 disposed between the N-CGL3 892 and the HTL4 920.

Each of the N-CGL1 692, the N-CGL2 792 and the N-CGL3 892 injects electrons to the EML1 640 of the first emitting part 600, the EML2 740 of the second emitting part 700 and the EML3 840 of the third emitting part 800, respectively, and each of the P-CGL1 694, the P-CGL2 794 and the P-CGL3 894 injects holes to the EML2 740 of the second emitting part 700, the EML3 840 of the third emitting part 800 and the EML4 940 of the fourth emitting part 900, respectively.

Each of the N-CGL1 692, the N-CGL2 792 and the N-CGL3 892 can be an organic layer doped with an alkali metal such as Li, Na, K and Cs and/or an alkaline earth metal such as Mg, Sr, Ba and Ra. For example, the contents of the alkali metal or the alkaline earth metal in each of the N-CGL1 692, the N-CGL2 792 and the N-CGL3 892 can be between about 0.01 wt % and about 30 wt %.

In one example embodiment, each of the P-CGL1 694, the P-CGL2 794 and the P-CGL3 894 can include, but is not limited to, inorganic material selected from the group consisting of WOₓ, MoOₓ, Be2O₃, V₂O₅ and combinations thereof. In another example embodiment, each of the P-CGL1 694, the P-CGL2 794 and the P-CGL3 894 can include the hole transporting material doped with the hole injecting material (e.g., HAT-CN, F4-TCNQ, F6-TCNNQ). The contents of the hole injecting material in each of the P-CGL1 694, the P-CGL2 794 and the P-CGL3 894 can be, but is not limited to, about 2 wt % to about 15 wt %.

In the OLED D2, two of the first to fourth emitting parts 600, 700, 800 and 900 emits blue color light, another of the first to fourth emitting parts 600, 700, 800 and 900 emits green color light, and the rest of the first to fourth emitting parts 600, 700, 800 and 900 emits blue-red color lights, so that the OLED D2 can implement white (W) emission. However, these emitting parts can be configured to emit different color lights as needed.

Hereinafter, the OLED D2 where the first emitting part 600 emits red-blue color lights, the second and fourth emitting parts 700 and 900 emits blue color light and the third emitting part 800 emits green color light will be described in detail.

The EML1 640 includes a red emitting material layer (R-EML1) 650, a first blue emitting material layer (B-EML1) 660A disposed between the R-EML 650 and the CGL1 690 and a second blue emitting material layer (B-EML2) 660B disposed between the B-EML1 660A and the CGL1 690. The R-EML 650 includes a red host 652 and a red emitter (red dopant) 654. The B-EML1 660A includes a first blue host 662a and a first blue emitter (first blue dopant) 664a, and the B-EML2 660B includes a second blue host 662b and a second blue emitter (second blue dopant) 664b. The kinds, charge mobility, energy level and contents of the red host 642, the red emitter 654, the first blue host 662a, the first blue emitter 664a, the second blue host 662b and the second blue emitter 664b can be identical to corresponding materials with referring to FIGS. 3 and 6.

Each of the EML2 740 and the EML4 940 can be a third blue emitting material layer (B-EML3) and a fourth blue emitting material layer (B-EML4), respectively. Each of the EML2 740 and the EML4 940 can be independently a blue EML, a sky-blue EML or a deep-blue EML. Each of the EML2 740 and the EML4 940 can include a blue host and a blue emitter (blue dopant).

The blue host in each of the EML2 740 and the EML4 940 can include at least one of a P-type blue host and an N-type blue host. The blue emitter in each of the EML2 740 and the EML4 940 can include at least one of blue phosphorescent material, blue fluorescent material and blue delayed fluorescent material.

In one example embodiment, the blue host in each of the EML2 740 and the EML4 940 can be identical to the first blue host 662a and/or the second blue host 662b. In another example embodiment, the blue host in each of the EML2 740 and the EML4 940 can independently include, but is not limited to, mCP, 9-(3-(9H-carbazol-9-yl)phenyl)-9H-carbazole-3-carbonitrile (mCP-CN), mCBP, CBP-CN, 9-(3-(9H-Carbazol-9-yl)phenyl)-3-(diphenylphosphoryl)-9H-carbazole (mCPPO1) 3,5-Di(9H-carbazol-9-yl)biphenyl (Ph-mCP), TSPO1,9-(3′-(9H-carbazol-9-yl)-[1,1′-biphenyl]-3-yl)-9H-pyrido[2,3-b]indole (CzBPCb), Bis(2-methylphenyl)diphenylsilane (UGH-1), 1,4-Bis(triphenylsilyl)benzene (UGH-2), 1,3-Bis(triphenylsilyl)benzene (UGH-3), 9,9-Spirobifluoren-2-yl-diphenyl-phosphine oxide (SPPO1), 9,9′-(5-(Triphenylsilyl)-1,3-phenylene)bis(9H-carbazole) (SimCP) and/or combinations thereof.

The blue emitter in each of the EML2 740 and the EML4 940 can be, but is not limited to, the first blue emitter 664a and/or the second blue emitter 664b. The blue host in the EML2 740 can be identical to or different form the blue host in the EML4 940. The blue emitter in the EML2 740 can be identical to or different from the blue emitter in the EML4 940.

The contents of the blue host in each of the EML2 740 and the EML4 940 can be about 50 wt % to about 99 wt %, for example, about 80 wt % to about 95 wt %, and the contents of the blue emitter in each of the EML2 740 and the EML4 940 can be about 1 wt % to about 50 wt %, for example, about 5 wt % to about 20 wt %, but is not limited thereto. When each of the EML2 740 and the EML4 940 includes a P-type blue host and an N-type blue host, the P-type blue host and the N-type blue host in each of the EML2 740 and the EML4 940 can be admixed, but is not limited to, with a weight ratio of about 4:1 to about 1:4, for example about 3:1 to about 1:3.

The EML3 840 can include a green host and a green emitter (green dopant). The green host in the EML3 840 can include a P-type green host and/or an N-type green host. The green emitter in the EML3 840 can include at least one of green phosphorescent material, green fluorescent material and green delayed fluorescent material.

As an example, the green host in the EML3 840 can include, but is not limited to, mCP-CN), CBP, mCBP, DPEPO, PPT, TmPyPB, PYD-2Cz, DCzDBT, DCzTPA, pCzB-2CN, mCzB-2CN, TSPO1, CCP, 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicarbazole, BCzPh, TCP, TCTA, CDBP, DMFL-CBP, Spiro-CBP, TCz1 and/or combinations thereof.

The green emitter in the EML3 840 can include, but is not limited to, [Bis(2-phenylpyridine)](pyridyl-2-benzofuro[2,3-b]pyridine)iridium, Tris[2-phenylpyridine]iridium(III) (Ir(ppy)₃), fac-Tris(2-phenylpyridine)iridium(III) (fac-Ir(ppy)₃), Bis(2-phenylpyridine)(acetylacetonate)iridium(III) (Ir(ppy)₂(acac)), Tris[2-(p-tolyl)pyridine]iridium(III) (Ir(mppy)₃), Bis(2-(naphthalene-2-yl)pyridine)(acetylacetonate)iridium(III) (Ir(npy)₂acac), Tris(2-phenyl-3-methyl-pyridine)iridium (Ir(3mppy)₃), fac-Tris(2-(3-p-xylyl)phenyl)pyridine iridium (III) (TEG) and/or combinations thereof.

The contents of the green host in the EML3 840 can be about 50 wt % to about 99 wt %, for example, about 80 wt % to about 95 wt %, and the contents of the green emitter in the EML3 840 can be about 1 wt % to about 50 wt %, for example, about 5 wt % to about 20 wt %, but is not limited thereto. When the EML3 840 includes a P-type green host and an N-type green host, the P-type green host and the N-type green host in the EML3 840 can be admixed, but is not limited to, with a weight ratio of about 4:1 to about 1:4, for example about 3:1 to about 1:3.

Two blue emitting material layers (B-EML1 and B-EML2) 660A and 660B are disposed adjacently to the red emitting material layer (R-EML) 650, and each of the B-EML1 660A and the B-EML2 660B includes the first blue host 662a and the second blue host 662b, respectively, each of which has controlled charge mobility and/or energy levels. Stable blue luminous efficiency can be maintained as the exciton recombination zone is formed within the EML1 640. Stabile red luminous lifespan can be secured and the driving voltage of the OLED D2 cannot be raised by preventing exciton quenching. In addition, the luminous properties of the OLED D2 can be further improved owing to the tandem structure.

### Example 1 (Ex.1): Fabrication of OLED

An organic light emitting diode where a red emitting material layer, a first blue emitting material layer having a first blue host with relatively excellent hole mobility and a second blue emitting material layer having a second blue host with relatively excellent electron mobility are disposed adjacently to each other was fabricated. A glass substrate onto which ITO (1200 Å) was coated as a thin film was washed and ultrasonically cleaned by solvent such as isopropyl alcohol, acetone and dried at 100° ° C. oven. The substrate was transferred to a vacuum chamber for depositing emissive layer as the following order:

Hole injection layer (TAPC, 100 Å); hole transport layer (NPB, 80 Å); red emitting material layer (host (TCTA, 98 wt %), red emitter Ir(piq)₃, 2 wt %), 100 Å); first blue emitting layer (host (Compound 1-1 in Chemical Formula 2, hole mobility 2.8E-06 cm²/(V·s), electron mobility 1.2E-05 cm²/(V·s), 98 wt %), blue emitter (DABNA-1 below, 2 wt %), 100 Å); second blue emitting material layer (host (MADN, hole mobility 1.1E-09 cm²/(V·s), electron mobility 2.5E-4 cm²/(V·s), 98 wt %), blue emitter (DABNA-1, 2 wt %), 100 Å); electron transport layer (TPBi, 220 Å); electron injection layer (LiF, 15 Å); and cathode (Al).

The fabricated OLED was encapsulated with glass and transferred to a dry box to form a film and then encapsulated with UV-cured epoxy and water getter. The structures of materials of hole injecting material, hole transporting material, red host, red emitter, blue emitter and electron transporting materials are illustrated in the following:

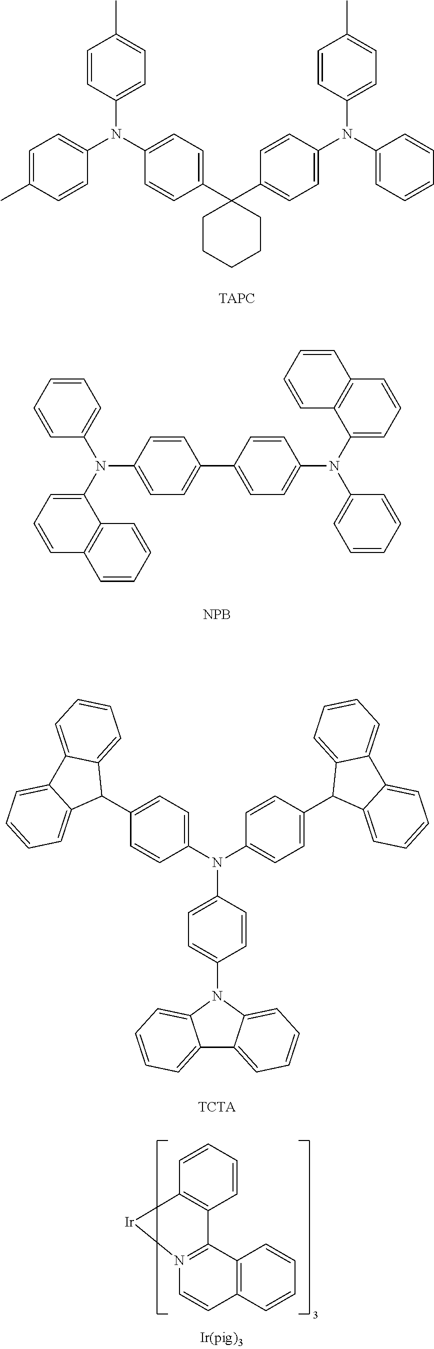

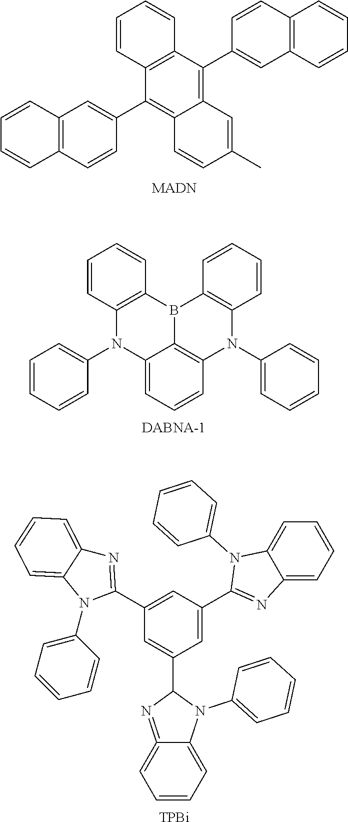

### Examples 2 (Ex. 2): Fabrication of OLEDs

An OLED was fabricated using the same procedure and the same material as Example 1, except that the second blue emitting material layer includes only the MADN of the host without the blue emitter.

### Comparative Example 1 (Ref. 1): Fabrication of OLEDs

An OLED was fabricated using the same procedure and the same material as Example 1, except that the blue emitting material layer was changed to a single-layered blue emitting material layer including a blue host MADN (98 wt %) and blue emitter DABNA-1 (2 wt %) with a thickness of 200 Å instead of dual blue emitting material layers.

### Comparative Example 2 (Ref. 2): Fabrication of OLEDs

An OLED was fabricated using the same procedure and the same material as Example 1, except that the blue emitting material layer was changed to a single-layered blue emitting material layer including a blue host Compound 1-1 in Chemical Formula 2 (98 wt %) and blue emitter DABNA-1 (2 wt %) with a thickness of 200 Å instead of dual blue emitting material layers

### Experimental Example 1: Measurement of Luminous Properties of OLEDs

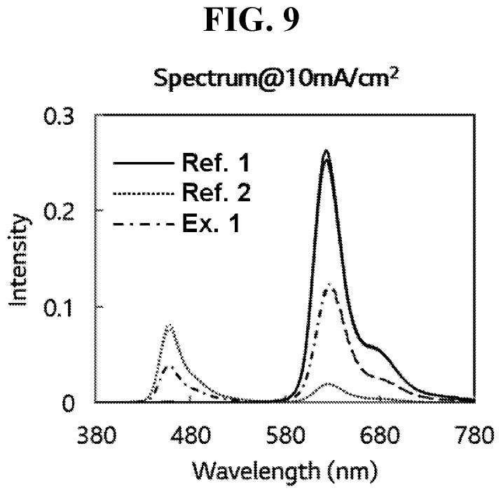

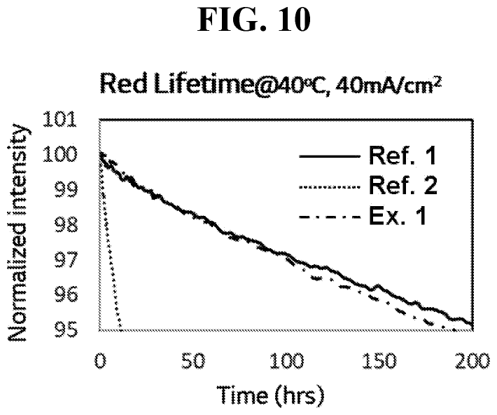

The luminous properties for each of the OLEDs, fabricated in Examples 1 to 2 and Comparative Examples 1 to 2, were measured. Each of the OLEDs, fabricated in Examples 1 to 2 and Comparative Examples 1 to 2 was connected to an external power source and then luminous properties for all the OLEDs were evaluated using a constant current source (KEITHLEY) and a photometer PR650 at room temperature. In particular, the electroluminescence (EL) spectrum for the OLEDs, and the driving voltage (V), red external quantum efficiency (EQE), blue EQE and the lifetime (T95, relative value) of the red light at which the luminance was reduced to 95% from initial luminance were measured at a current density 40 mA/cm² and at 40° C. The measurement results are indicated in the following Table 1 and FIGS. 9 to 10.

TABLE 1
Luminous Properties of OLED

| | V | Red | Blue | Red T⁹⁵ |
|---|---|---|---|---|
| Sample | (10 mA/cm²) | EQE (%) | EQE (%) | (hr) |
| Ref. 1 | 3.04 | 20.2 | 0.02 | 206 |
| Ref. 2 | 3.32 | 1.6 | 3.46 | 11 |
| Ex. 1 | 3.25 | 10.1 | 1.72 | 188 |
| Ex. 2 | 3.14 | 9.3 | 1.54 | 118 |

As indicated in Table 1, the blue emission efficiency in the OLED fabricated in Comparative Example 1 was very low and the red efficiency in the OLED fabricated in Comparative Example 2 was very low. Also, the red light lifetime in the OLED fabricated in Comparative Example 2 was lowered considerably because holes and electrons are leaked to the electron transport layer and thereby exciton annihilation in the interface between the blue emitting material layer and the electron transport layer. When the single-layered blue emitting material layer is disposed adjacently to the red emitting material layer, the difference between the blue and red emission efficiency were great and the luminous lifetime was reduced greatly so that there is limitation for utilizing as a blue-red junction diode.

On the contrary, compared to the OLED fabricated in Reference Example 1, in the OLED fabricated in Example 1, the blue EQE was increased by 86 times and red EQE and red luminous lifetime was maintained at stable levels. In addition, compared to the OLED fabricated in Comparative Example 1, in the OLED fabricated in Example 1, the driving voltage was lowered, red EQE was improved by 531.2%, red luminous lifetime was improved by 160.9%, and the blue EQE was maintained at stable levels. In the OLED fabricated in Example 1, stable blue luminous efficiency was secured with the improved red luminous lifetime.

In addition, as Example 2, red and blue colors can be emitted stably in the OLED where the second blue emitting material layer includes only the second blue host. The second blue emitting material layer acts as another emitting material layer inducing stable light emissions beyond the role of a hole blocking layer.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

What is claimed is:

1. An organic light emitting diode comprising:
a first electrode;
a second electrode facing the first electrode; and
an emissive layer disposed between the first electrode and second electrode, and including at least one emitting material layer,
wherein the at least one emitting material layer includes:
a red emitting material layer;
a first blue emitting material layer disposed between the red emitting material layer and the second electrode, and including a first blue host; and
a second blue emitting material layer disposed between the first blue emitting material layer and the second electrode, and including a second blue host, and
wherein the first blue host has a hole mobility faster than a hole mobility of the second blue host.

2. The organic light emitting diode of claim 1, wherein the first blue host has an electron mobility slower than an electron mobility of the second blue host.

3. The organic light emitting diode of claim 1, wherein the second blue host has a highest occupied molecular orbital (HOMO) energy level lower than a HOMO energy level of the first blue host.

4. The organic light emitting diode of claim 1, wherein the first blue host includes an organic compound having the following structure of Chemical Formula 1: 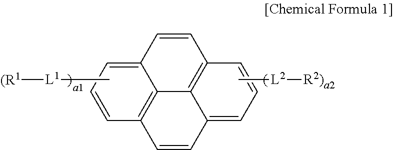
wherein, in Chemical Formula 1,
each of R¹ and R² is independently an unsubstituted or substituted C₆-C₃₀ aryl group or an unsubstituted or substituted C₃-C₃₀ hetero aryl group;
each of L¹ and L² is independently a single bond, an unsubstituted or substituted C₆-C₃₀ arylene group or an unsubstituted or substituted C₃-C₃₀ hetero arylene group; and
each of a1 and a2 is independently 1, 2 or 3, where each R¹-L¹- is identical to or different from each other when a1 is 2 or 3 and each R²-L²- is identical to or different from each other when a2 is 2 or 3.

5. The organic light emitting diode of claim 4, wherein in Chemical Formula 1:
each R¹ is independently selected from substituted or unsubstituted dibenzothiophenyl, substituted or unsubstituted benzofuran;
each L¹ is independently selected from direct bond, phenyl, naphthyl or anthracenyl;
each R² is independently selected from substituted or unsubstituted dibenzothiophenyl, substituted or unsubstituted benzofuran; and
each L² is independently selected from direct bond, phenyl, naphthyl or anthracenyl.

6. The organic light emitting diode of claim 4, wherein in Chemical Formula 1:
each L¹ is independently selected from substituted or unsubstituted dibenzothiophenyl, substituted or unsubstituted benzofuran;
each R¹ is independently selected from phenyl, naphthyl or anthracenyl;
each L² is independently selected from substituted or unsubstituted dibenzothiophenyl, substituted or unsubstituted benzofuran; and
each R² is independently selected from phenyl, naphthyl or anthracenyl.

7. The organic light emitting diode of claim 4, wherein in Chemical Formula 1:
each (R¹)ₐ₁-L¹- moiety is independently selected from the group consisting of: 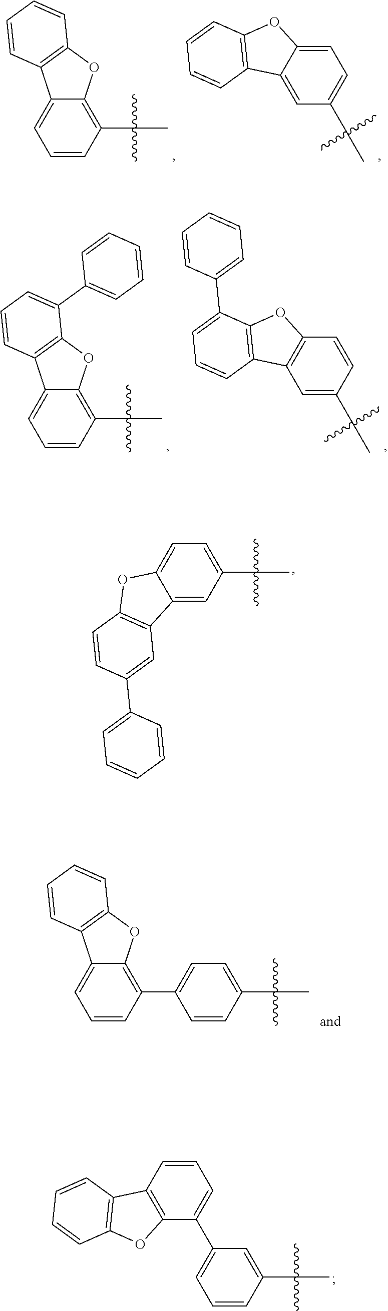
each (R²)ₐ₂-L²- is independently selected from the group consisting of: phenyl,

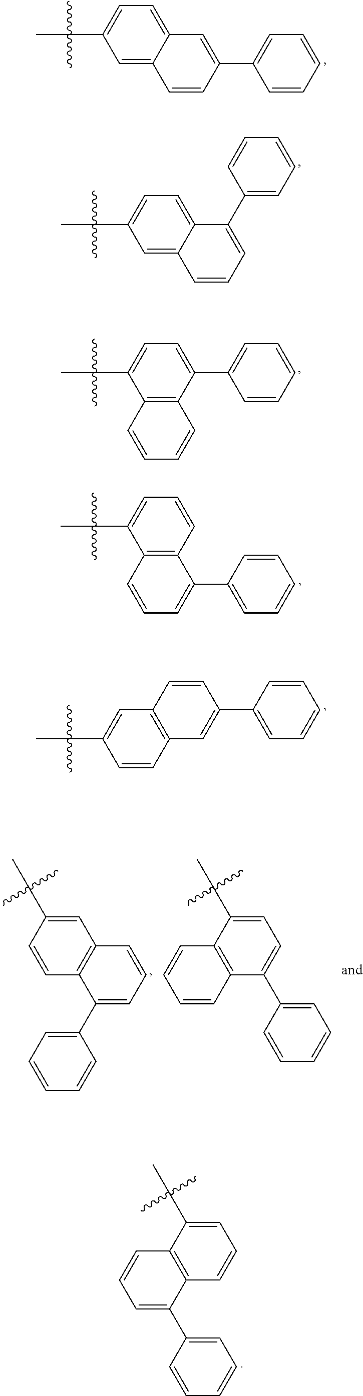

8. The organic light emitting diode of claim 1, wherein the first blue host includes at least one of the following organic compounds:

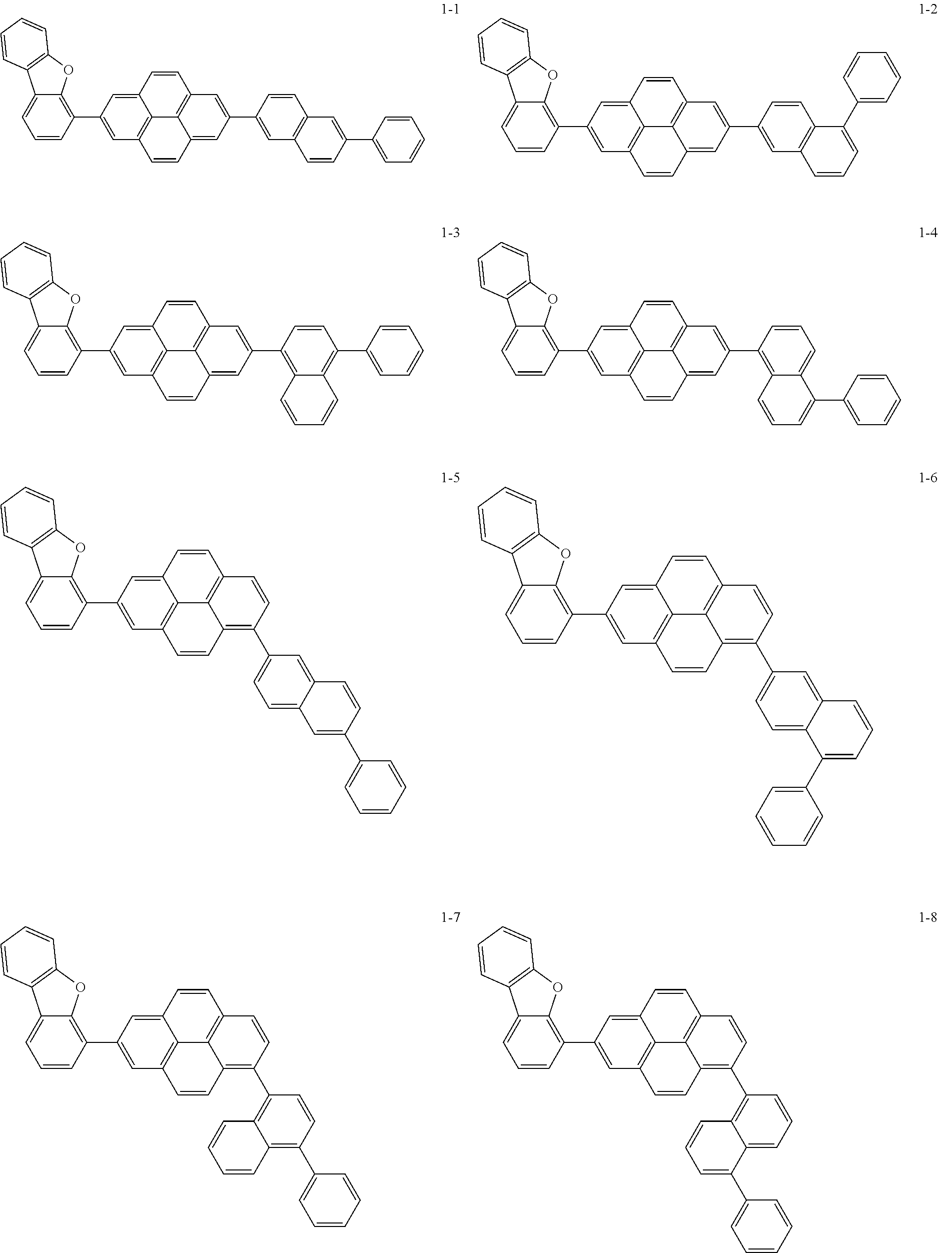

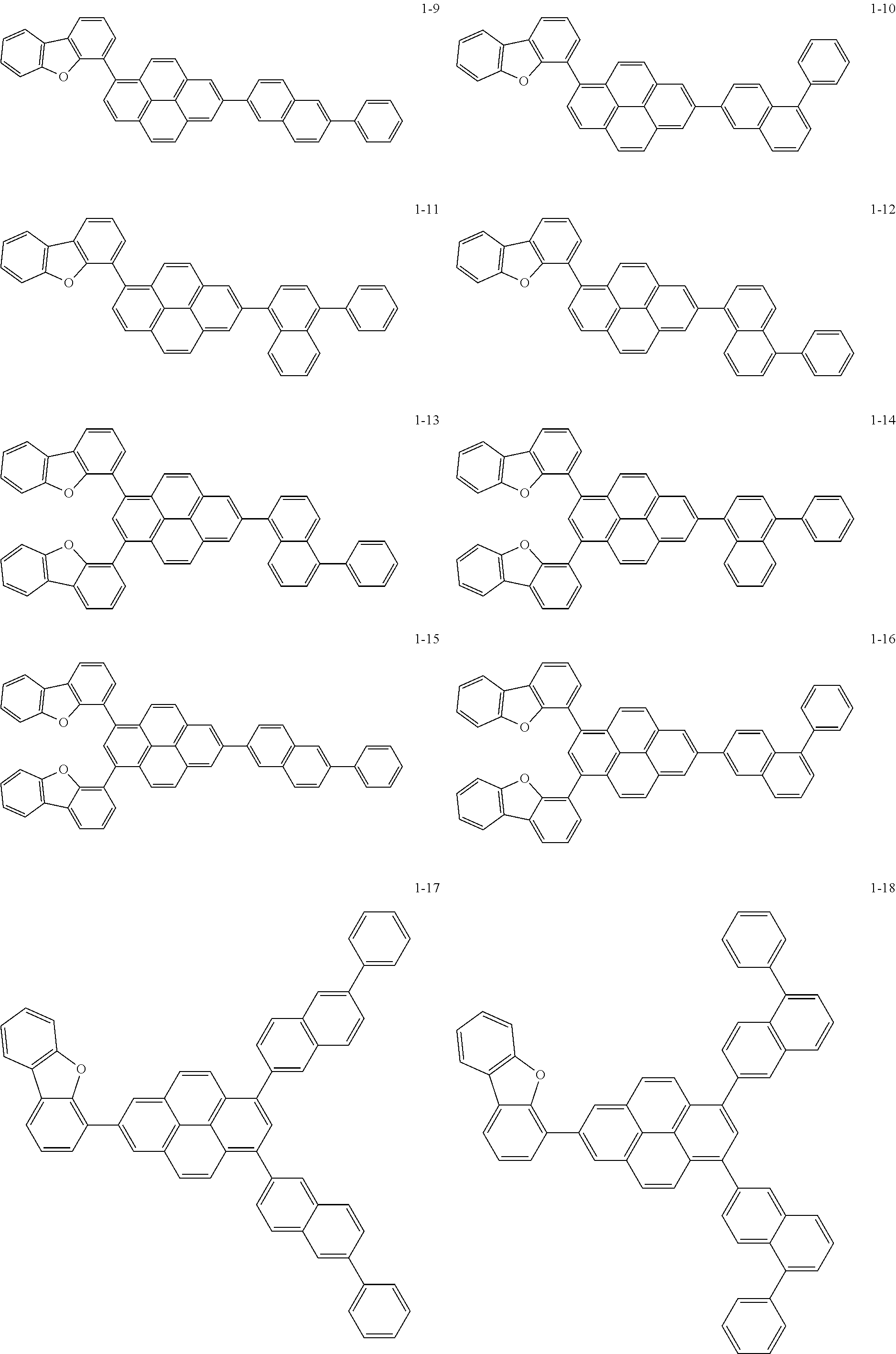

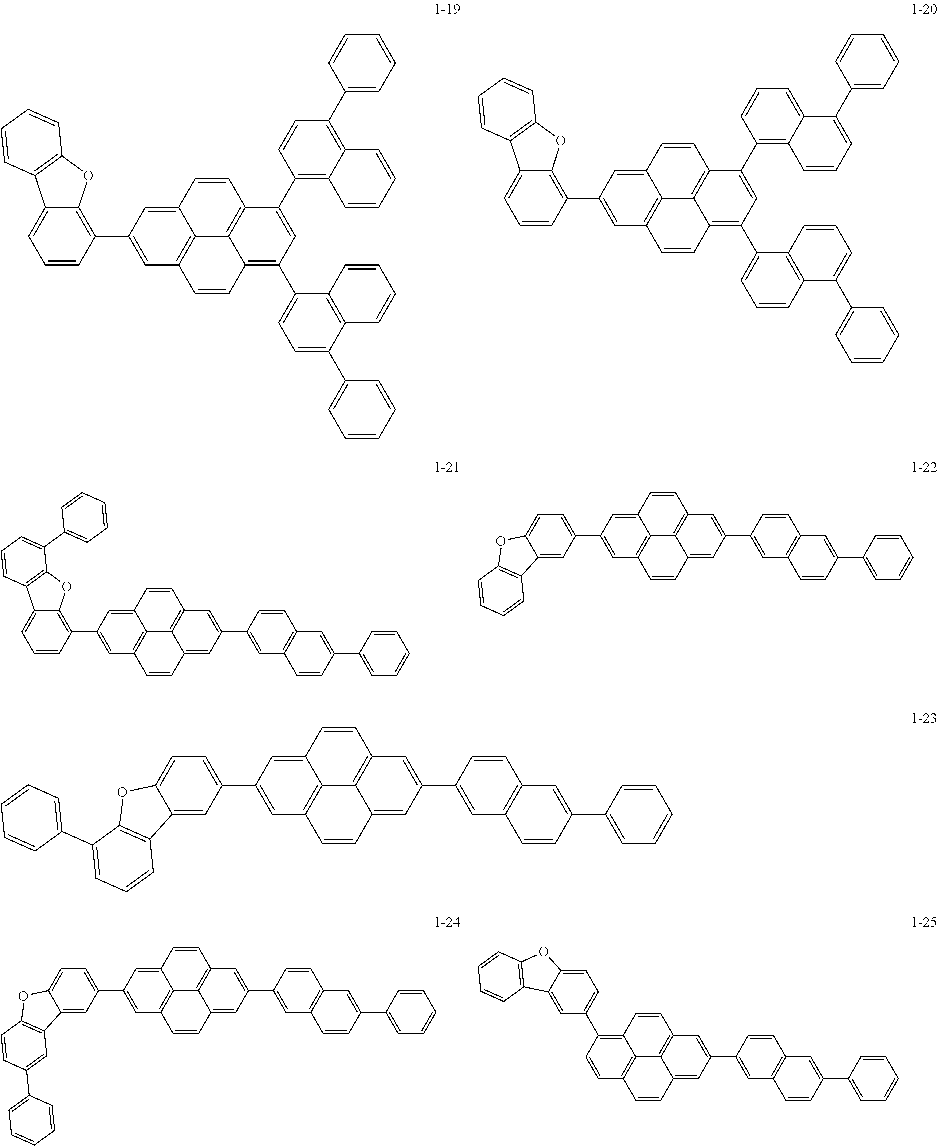

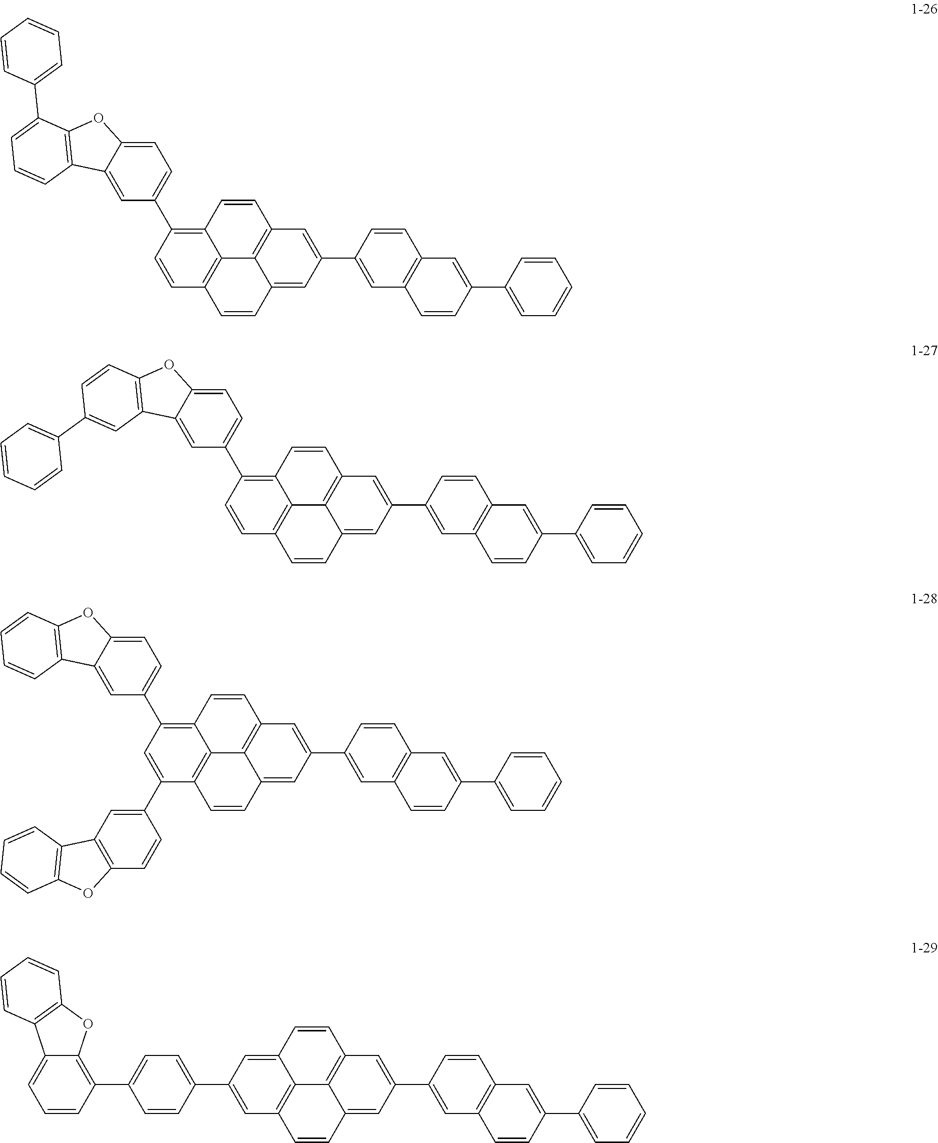 [SMILES: c1ccc(-c2ccc3cc(-c4cc5ccc6ccc(-c7ccc8oc9c(-c%10ccccc%10)cccc9c8c7)c7ccc(c4)c5c67)ccc3c2)cc1 ; c1ccc(-c2ccc3cc(-c4cc5ccc6ccc(-c7ccc8oc9ccc(-c%10ccccc%10)cc9c8c7)c7ccc(c4)c5c67)ccc3c2)cc1 ; c1ccc(-c2ccc3cc(-c4cc5ccc6c(-c7ccc8oc9ccccc9c8c7)cc(-c7ccc8oc9ccccc9c8c7)c7ccc(c4)c5c67)ccc3c2)cc1 ; c1ccc(-c2ccc3cc(-c4cc5ccc6cc(-c7ccc(-c8cccc9c8oc8ccccc89)cc7)cc7ccc(c4)c5c67)ccc3c2)cc1]

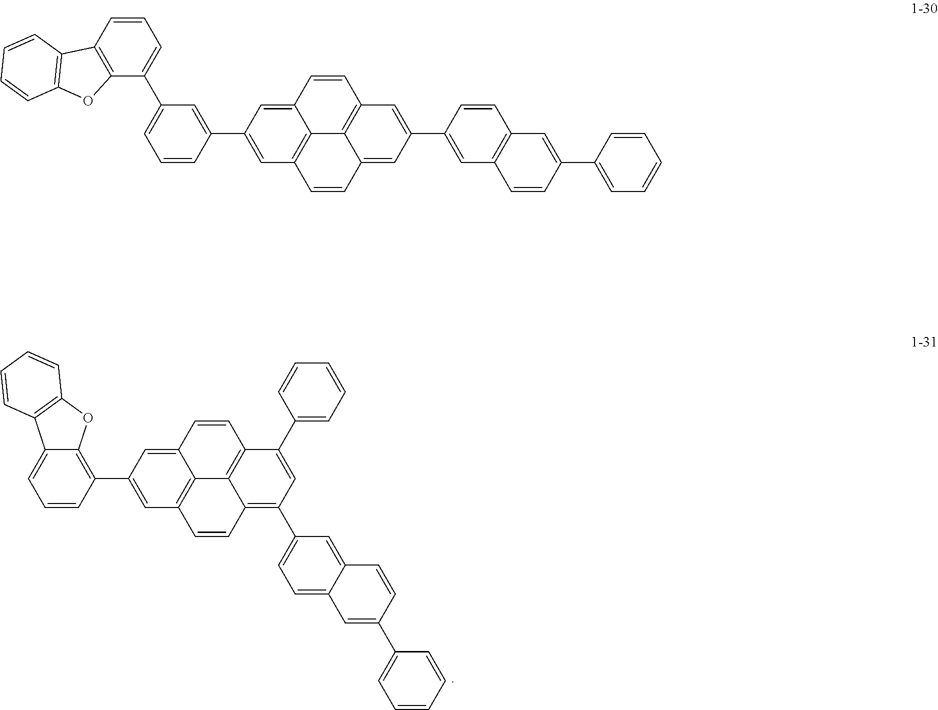 [SMILES: c1ccc(-c2ccc3cc(-c4cc5ccc6cc(-c7cccc(-c8cccc9c8oc8ccccc89)c7)cc7ccc(c4)c5c67)ccc3c2)cc1 ; c1ccc(-c2ccc3cc(-c4cc(-c5ccccc5)c5ccc6cc(-c7cccc8c7oc7ccccc78)cc7ccc4c5c67)ccc3c2)cc1]

9. The organic light emitting diode of claim 1, wherein the second blue host includes an organic compound having the following structure of Chemical Formula 3: 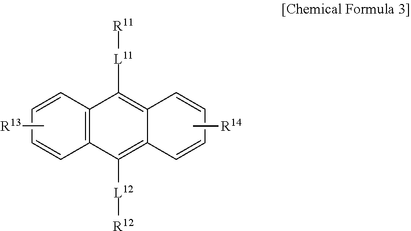
wherein, in Chemical Formula 3,
each of R¹¹ and R¹² is independently an unsubstituted or substituted C₆-C₃₀ aryl group or an unsubstituted or substituted C₃-C₃₀ hetero aryl group;
each of R¹³ and R¹⁴ is independently hydrogen, an unsubstituted or substituted C₁-C₂₀ alkyl group, an unsubstituted or substituted C₆-C₃₀ aryl group or an unsubstituted or substituted C₃-C₃₀ hetero aryl group; and
L¹¹ and L¹² is independently a single bond, an unsubstituted or substituted C₆-C₃₀ arylene group or an unsubstituted or substituted C₃-C₃₀ hetero arylene group.

10. The organic light emitting diode of claim 1, wherein the second blue host is selected from the group consisting of 9,10-di(naphthalen-2-yl)anthracene, 2-methyl-9,10-bis(naphthalen-2-yl)anthracene, 2-tert-Butyl-9,10-di(naphthen-2-yl)anthracene, 9,10-di(naphthalen-2-yl)-2-phenylanthracene, 9-phenyl-10-(p-tolyl)anthracene, 9-(1-naphthyl)-10-(p-tolyl)anthracene, 9-(2-naphthyl)-10-(p-tolyl)anthracene, 2-(3-(10-phenylanthracen-9-yl)-phenyl)dibenzo[b,d]furan, 2-(4-(10-phenylanthracen-9-yl)phenyl)dibenzo[b,d]furan and combinations thereof.

11. The organic light emitting diode of claim 1, wherein the emissive layer includes:
a first emitting part disposed between the first electrode and the second electrode;
a second emitting part disposed between the first emitting part and the second electrode;
a third emitting part disposed between the second emitting part and the second electrode;
a fourth emitting part disposed between the third emitting part and the second electrode;
a first charge generation layer disposed between the first emitting part and the second emitting part;
a second charge generation layer disposed between the second emitting part and the third emitting part; and
a third charge generation layer disposed between the third emitting part and the fourth emitting part, and
wherein one of the first to fourth emitting parts includes the at least one emitting material layer.

12. An organic light emitting diode comprising:
a first electrode;
a second electrode facing the first electrode; and
an emissive layer disposed between the first electrode and the second electrode,
wherein the emissive layer includes:
a first emitting part disposed between the first electrode and the second electrode;
a second emitting part disposed between the first emitting part and the second electrode;
a third emitting part disposed between the second emitting part and the second electrode;
a fourth emitting part disposed between the third emitting part and the second electrode;
a first charge generation layer disposed between the first emitting part and the second emitting part;
a second charge generation layer disposed between the second emitting part and the third emitting part; and
a third charge generation layer disposed between the third emitting part and the fourth emitting part,
wherein the first emitting part includes:
a red emitting material layer disposed between the first electrode and the first charge generation layer;
a first blue emitting material layer disposed between the red emitting material layer and the first charge generation layer and including a first blue host; and
a second blue emitting material layer disposed between the first blue emitting material layer and the first charge generation layer,
wherein the second emitting part includes a third blue emitting material layer, the fourth emitting part includes a fourth blue emitting material layer, and the third emitting part includes a green emitting material layer, and
wherein the first blue host has a hole mobility faster than a hole mobility of the second blue host.

13. The organic light emitting diode of claim 12, wherein the first blue host has an electron mobility slower than an electron mobility of the second blue host.

14. The organic light emitting diode of claim 12, wherein the first blue host includes an organic compound having the following structure of Chemical Formula 1: 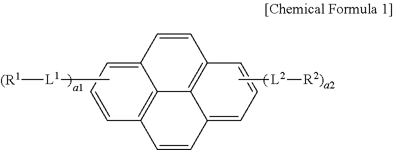
wherein, in Chemical Formula 1,
each of R¹ and R² is independently an unsubstituted or substituted C₆-C₃₀ aryl group or an unsubstituted or substituted C₃-C₃₀ hetero aryl group;
each of L¹ and L² is independently a single bond, an unsubstituted or substituted C₆-C₃₀ arylene group or an unsubstituted or substituted C₃-C₃₀ hetero arylene group; and
each of a1 and a2 is independently 1, 2 or 3, where each R¹-L¹- is identical to or different from each other when a1 is 2 or 3 and each R²-L²- is identical to or different from each other when a2 is 2 or 3.

15. The organic light emitting diode of claim 14, wherein in Chemical Formula 1:
each R′ is independently selected from substituted or unsubstituted dibenzothiophenyl, substituted or unsubstituted benzofuran;
each L¹ is independently selected from direct bond, phenyl, naphthyl or anthracenyl;
each R² is independently selected from substituted or unsubstituted dibenzothiophenyl, substituted or unsubstituted benzofuran; and
each L² is independently selected from direct bond, phenyl, naphthyl or anthracenyl.

16. The organic light emitting diode of claim 14, wherein in Chemical Formula 1:
each L¹ is independently selected from substituted or unsubstituted dibenzothiophenyl, substituted or unsubstituted benzofuran;
each R¹ is independently selected from phenyl, naphthyl or anthracenyl;
each L² is independently selected from substituted or unsubstituted dibenzothiophenyl, substituted or unsubstituted benzofuran; and
each R² is independently selected from phenyl, naphthyl or anthracenyl.

17. The organic light emitting diode of claim 12, wherein in Chemical Formula 1:
each (R¹)ₐ₁-L′- moiety is independently selected from the group consisting of: 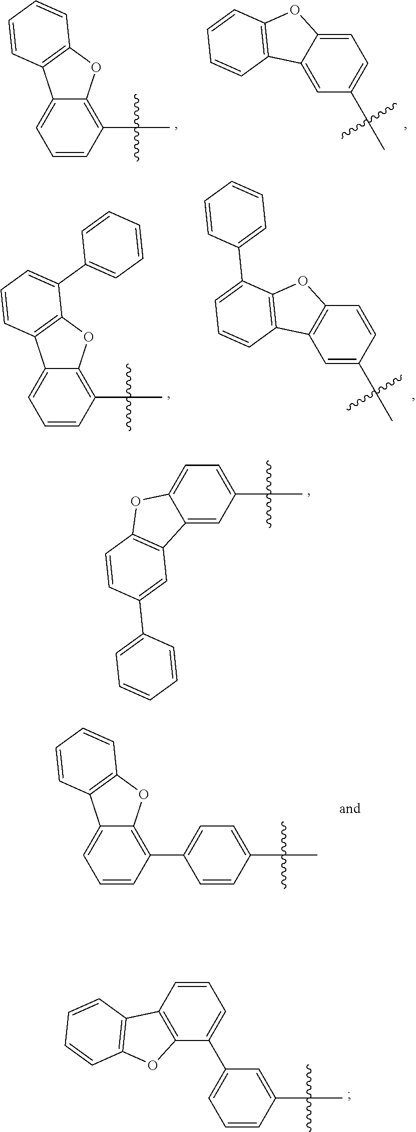
each (R²)ₐ₂-L²- is independently selected from the group consisting of: phenyl,

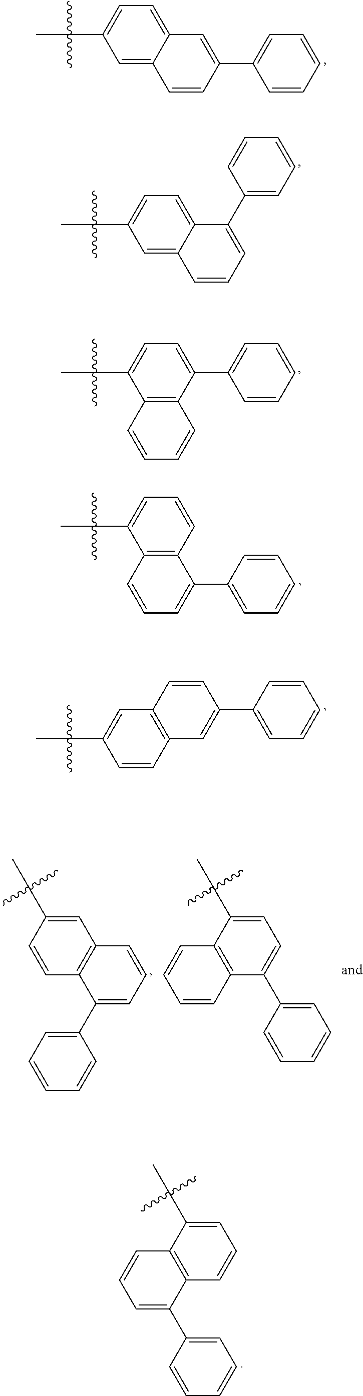

18. The organic light emitting diode of claim 12, wherein the first blue host includes at least one of the following organic compounds:

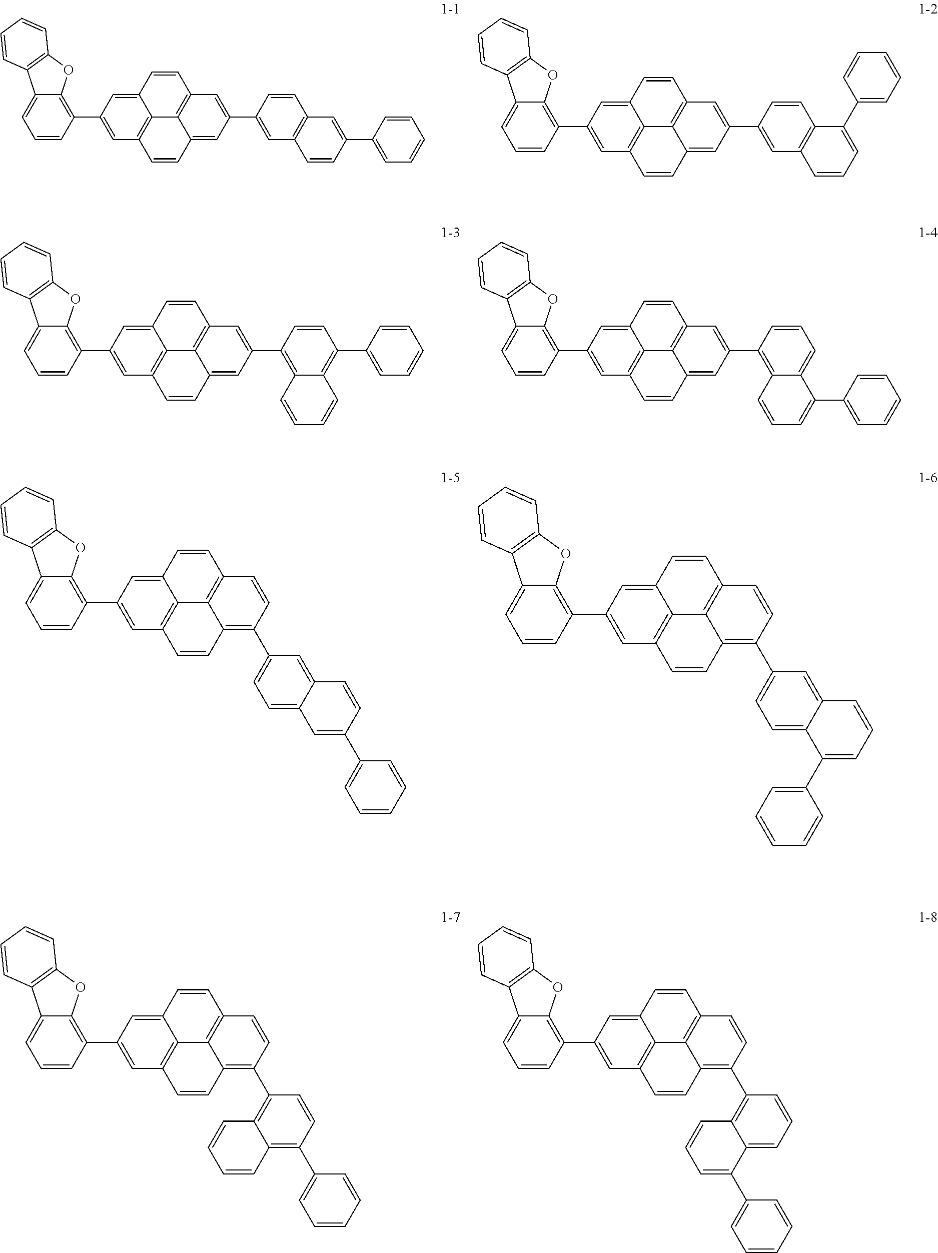

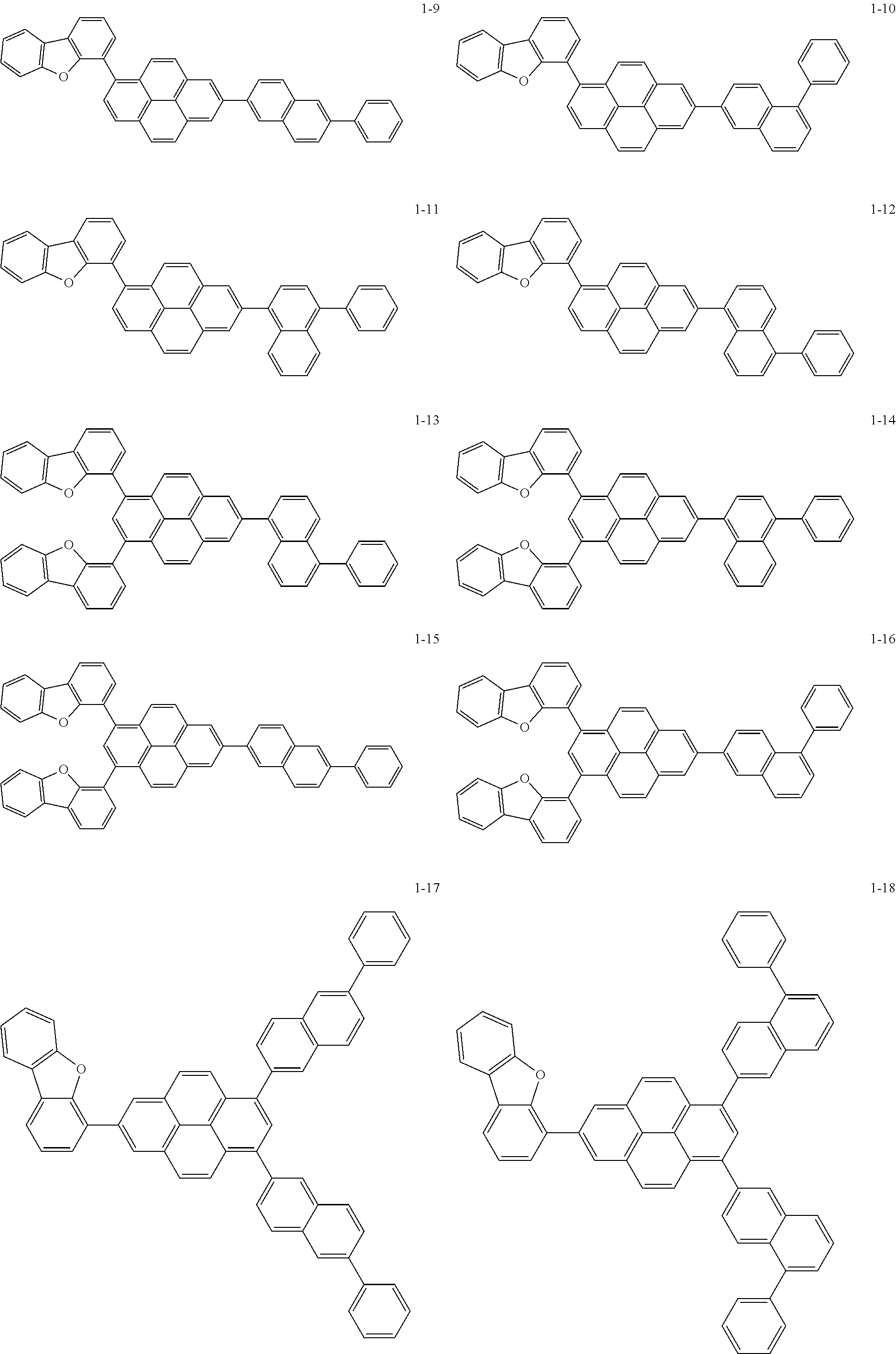

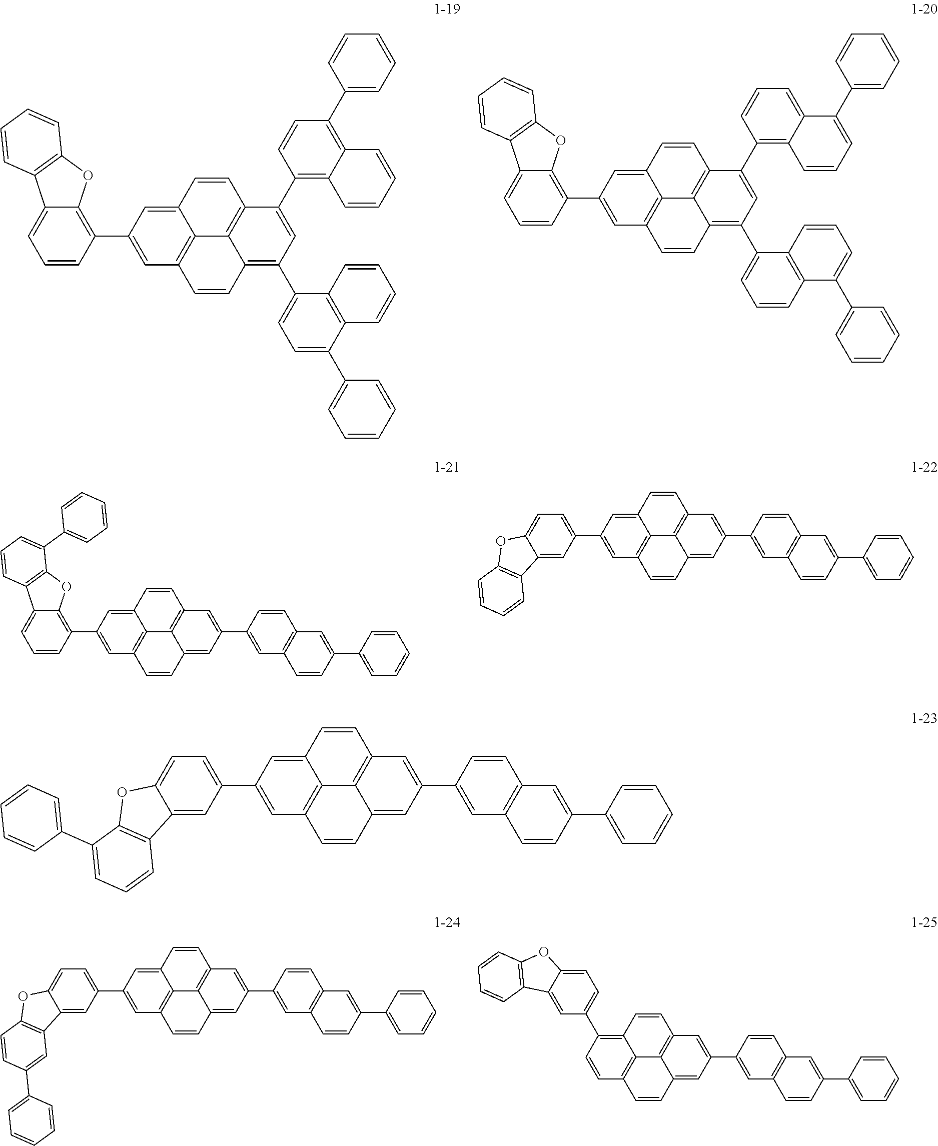

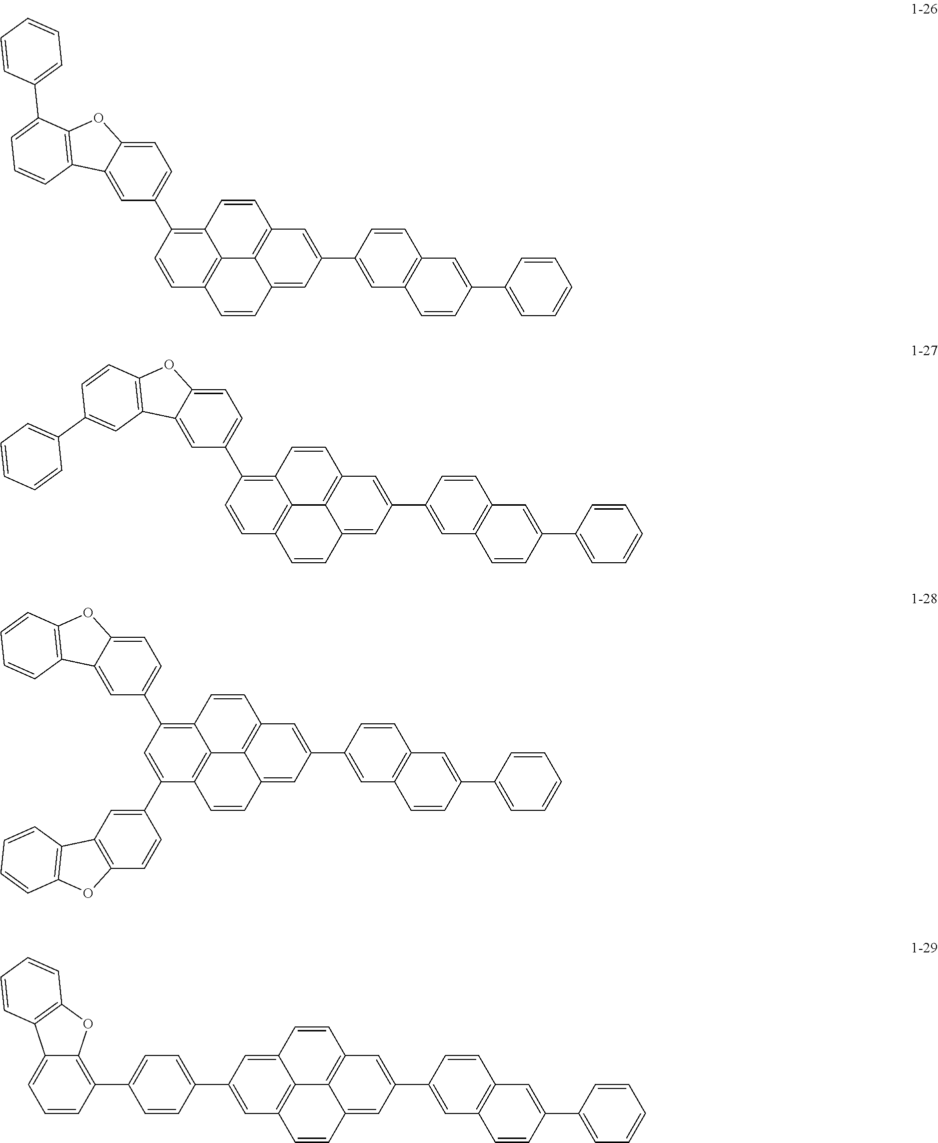 [SMILES: c1ccc(-c2ccc3cc(-c4cc5ccc6ccc(-c7ccc8oc9c(-c%10ccccc%10)cccc9c8c7)c7ccc(c4)c5c67)ccc3c2)cc1 ; c1ccc(-c2ccc3cc(-c4cc5ccc6ccc(-c7ccc8oc9ccc(-c%10ccccc%10)cc9c8c7)c7ccc(c4)c5c67)ccc3c2)cc1 ; c1ccc(-c2ccc3cc(-c4cc5ccc6c(-c7ccc8oc9ccccc9c8c7)cc(-c7ccc8oc9ccccc9c8c7)c7ccc(c4)c5c67)ccc3c2)cc1 ; c1ccc(-c2ccc3cc(-c4cc5ccc6cc(-c7ccc(-c8cccc9c8oc8ccccc89)cc7)cc7ccc(c4)c5c67)ccc3c2)cc1]

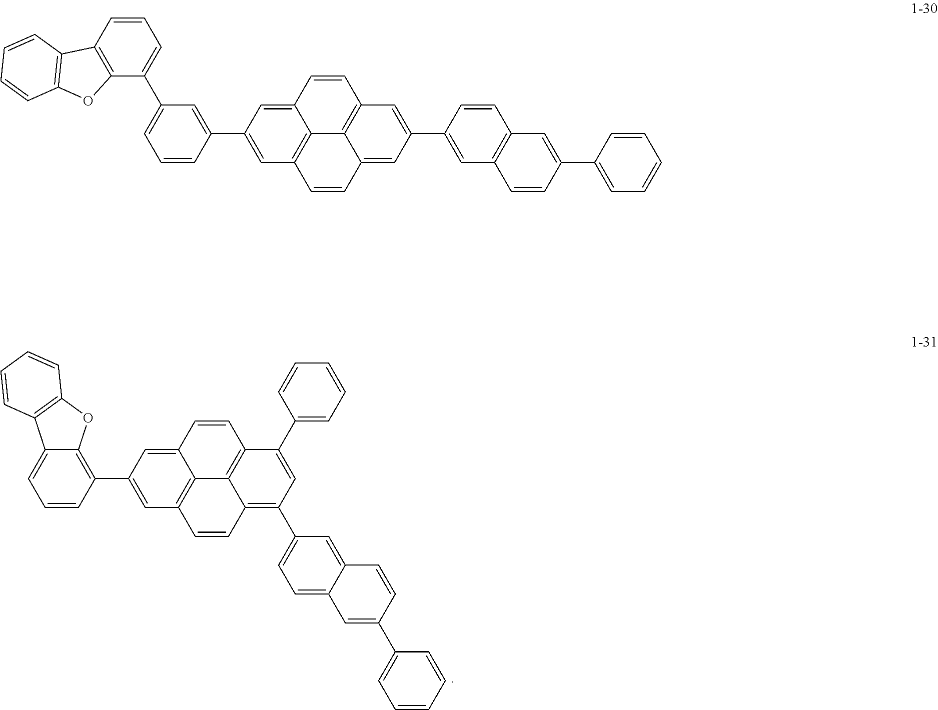 [SMILES: c1ccc(-c2ccc3cc(-c4cc5ccc6cc(-c7cccc(-c8cccc9c8oc8ccccc89)c7)cc7ccc(c4)c5c67)ccc3c2)cc1 ; c1ccc(-c2ccc3cc(-c4cc(-c5ccccc5)c5ccc6cc(-c7cccc8c7oc7ccccc78)cc7ccc4c5c67)ccc3c2)cc1]

19. The organic light emitting diode of claim 12, wherein the second blue host includes an organic compound having the following structure of Chemical Formula 3: 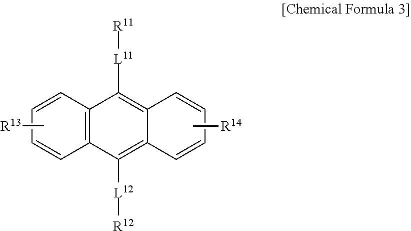
wherein, in Chemical Formula 3,
each of R¹¹ and R¹² is independently an unsubstituted or substituted C₆-C₃₀ aryl group or an unsubstituted or substituted C₃-C₃₀ hetero aryl group;
each of R¹³ and R¹⁴ is independently hydrogen, an unsubstituted or substituted C₁-C₂₀ alkyl group, an unsubstituted or substituted C₆-C₃₀ aryl group or an unsubstituted or substituted C₃-C₃₀ hetero aryl group; and
L¹ and L¹² is independently a single bond, an unsubstituted or substituted C₆-C₃₀ arylene group or an unsubstituted or substituted C₃-C₃₀ hetero arylene group.

20. The organic light emitting diode of claim 12, wherein the second blue host is selected from the group consisting of 9,10-di(naphthalen-2-yl)anthracene, 2-methyl-9,10-bis(naphthalen-2-yl)anthracene, 2-tert-Butyl-9,10-di(naphthen-2-yl)anthracene, 9,10-di(naphthalen-2-yl)-2-phenylanthracene, 9-phenyl-10-(p-tolyl)anthracene, 9-(1-naphthyl)-10-(p-tolyl)anthracene, 9-(2-naphthyl)-10-(p-tolyl)anthracene, 2-(3-(10-phenylanthracen-9-yl)-phenyl)dibenzo[b,d]furan, 2-(4-(10-phenylanthracen-9-yl)phenyl)dibenzo[b,d]furan and combinations thereof.

21. An organic light emitting device comprising:
a substrate; and
the organic light emitting diode of claim 1 over the substrate.

22. An organic light emitting device comprising:
a substrate; and
the organic light emitting diode of claim 12 over the substrate.
